(19) United States
(12) Patent Application Publication
(10) Pub. No.: US 2024/0114684 A1
(43) Pub. Date: Apr. 4, 2024

(54) SEMICONDUCTOR MEMORY DEVICE

(71) Applicant: Kioxia Corporation, Tokyo (JP)

(72) Inventor: Kazuaki TSUNODA, Kuwana (JP)

(73) Assignee: Kioxia Corporation, Tokyo (JP)

(21) Appl. No.: 18/338,442

(22) Filed: Jun. 21, 2023

(30) Foreign Application Priority Data
Sep. 22, 2022 (JP) 2022-150935

(51) Int. Cl. H10B 41/35; H10B 41/27; H10B 43/27; H10B 43/35

(52) U.S. Cl. CPC H10B 41/35; H10B 41/27; H10B 43/27; H10B 43/35

(57) ABSTRACT

A semiconductor memory device includes memory finger structures and a kerf region. The memory finger structures include a first stacked body including conductive layers and semiconductor columns opposed to the conductive layers. The kerf region includes a second stacked body including layers corresponding to at least a part of the conductive layers. A first region in the kerf region is arranged in a first direction with a part of the memory finger structures and includes a part of the second stacked body. A second region in the kerf region is arranged in the first direction with another part of the memory finger structures and does not include the second stacked body. A third region in the kerf region extends in a second direction along an end portion on the memory plane region side in the first direction of the kerf region and includes another part of the second stacked body.

### CROSS-REFERENCE TO RELATED APPLICATIONS

This application is based upon and claims the benefit of Japanese Patent Application No. 2022-150935, filed on Sep. 22, 2022, the entire contents of which are incorporated herein by reference.

### FIELD

### Background

Embodiments described herein relate generally to a semiconductor memory device.

### Description of the Related Art

There has been known a semiconductor memory device that includes a first stacked body including a plurality of conductive layers stacked in a stacking direction, a plurality of semiconductor columns extending in the stacking direction and opposed to the plurality of conductive layers, and a plurality of electric charge accumulating films disposed between the plurality of conductive layers and the plurality of semiconductor columns.

### BRIEF DESCRIPTION OF THE DRAWINGS

FIG. 1 is a schematic plan view illustrating a configuration of a memory die MD;

FIG. 2 is a schematic cross-sectional view illustrating a configuration of a part of the memory die MD;

FIG. 3 is a schematic cross-sectional view illustrating a configuration of a part of the memory die MD;

FIG. 4 is a schematic cross-sectional view illustrating a configuration of a part of the memory die MD;

FIG. 5 is a schematic cross-sectional view illustrating a configuration of a part of a memory cell region R_{MC};

FIG. 6 is a schematic cross-sectional view illustrating a configuration of a part of the memory cell region R_{MC};

FIG. 7 is a schematic cross-sectional view illustrating a configuration of a part of a hook-up region R_{HU};

FIG. 8 is a schematic cross-sectional view illustrating a configuration of a part of an inter-finger structure ST;

FIG. 9 is a schematic cross-sectional view illustrating a configuration of a part of an edge region R_{E};

FIG. 10 is a schematic cross-sectional view illustrating a configuration of a part of the edge region R_{E};

FIG. 11 is a schematic plan view illustrating a configuration of a part of a memory wafer MW;

FIG. 12 is a schematic cross-sectional view illustrating a configuration of a part of the memory wafer MW;

FIG. 13 is a schematic cross-sectional view exemplifying a configuration in a stacked body region R_{SS};

FIG. 14 is a schematic cross-sectional view exemplifying the configuration in the stacked body region R_{SS};

FIG. 15 is a schematic cross-sectional view illustrating a configuration of a part of the memory wafer MW;

FIG. 16 is a schematic cross-sectional view exemplifying a configuration in a non-stacked body region R_{SN};

FIG. 17 is a schematic cross-sectional view exemplifying the configuration in the non-stacked body region R_{SN};

FIG. 18 is a schematic cross-sectional view for describing a method of manufacturing the memory die MD;

FIG. 19 is a schematic cross-sectional view for describing the manufacturing method;

FIG. 20 is a schematic cross-sectional view for describing the manufacturing method;

FIG. 21 is a schematic cross-sectional view for describing the manufacturing method;

FIG. 22 is a schematic cross-sectional view for describing the manufacturing method;

FIG. 23 is a schematic cross-sectional view for describing the manufacturing method;

FIG. 24 is a schematic cross-sectional view for describing the manufacturing method;

FIG. 25 is a schematic cross-sectional view for describing the manufacturing method;

FIG. 26 is a schematic cross-sectional view for describing the manufacturing method;

FIG. 27 is a schematic cross-sectional view for describing the manufacturing method;

FIG. 28 is a schematic cross-sectional view for describing the manufacturing method;

FIG. 29 is a schematic cross-sectional view for describing the manufacturing method;

FIG. 30 is a schematic cross-sectional view for describing the manufacturing method;

FIG. 31 is a schematic cross-sectional view for describing the manufacturing method;

FIG. 32 is a schematic cross-sectional view for describing the manufacturing method;

FIG. 33 is a schematic cross-sectional view for describing the manufacturing method;

FIG. 34 is a schematic cross-sectional view for describing the manufacturing method;

FIG. 35 is a schematic cross-sectional view for describing the manufacturing method;

FIG. 36 is a schematic cross-sectional view for describing the manufacturing method;

FIG. 37 is a schematic cross-sectional view for describing the manufacturing method;

FIG. 38 is a schematic cross-sectional view for describing the manufacturing method;

FIG. 39 is a schematic cross-sectional view for describing the manufacturing method;

FIG. 40 is a schematic cross-sectional view for describing the manufacturing method;

FIG. 41 is a schematic cross-sectional view for describing the manufacturing method;

FIG. 42 is a schematic cross-sectional view for describing the manufacturing method;

FIG. 43 is a schematic cross-sectional view for describing the manufacturing method;

FIG. 44 is a schematic cross-sectional view for describing the manufacturing method;

FIG. 45 is a schematic cross-sectional view for describing the manufacturing method;

FIG. 46 is a schematic cross-sectional view for describing the manufacturing method;

FIG. 47 is a schematic cross-sectional view for describing the manufacturing method;

FIG. 48 is a schematic cross-sectional view for describing the manufacturing method;

FIG. 49 is a schematic cross-sectional view for describing the manufacturing method;

FIG. 50 is a schematic cross-sectional view for describing the manufacturing method;

FIG. 51 is a schematic cross-sectional view for describing the manufacturing method;

FIG. 52 is a schematic cross-sectional view for describing the manufacturing method;

FIG. 53 is a schematic cross-sectional view for describing the manufacturing method;

FIG. 54 is a schematic cross-sectional view for describing the manufacturing method;

FIG. 55 is a schematic plan view illustrating a configuration of a memory wafer MW′;

FIG. 56 is a schematic cross-sectional view for describing a method of manufacturing the memory wafer MW′;

FIG. 57 is a schematic plan view for describing a part of the manufacturing method of the memory wafer MW′;

FIG. 58 is a schematic plan view for describing a part of the manufacturing method of the memory wafer MW;

FIG. 59 is a schematic plan view illustrating a configuration of a memory die MD2;

FIG. 60 is a schematic cross-sectional view illustrating a configuration of a part of the memory die MD2;

FIG. 61 is a schematic cross-sectional view illustrating a configuration of a part of the memory die MD2;

FIG. 62 is a schematic cross-sectional view for describing a manufacturing process of the memory die MD;

FIG. 63 is a schematic cross-sectional view for describing the manufacturing process of the memory die MD;

FIG. 64 is a schematic cross-sectional view for describing a manufacturing process of the memory die MD2;

FIG. 65 is a schematic plan view for describing a part of the manufacturing method of the memory die MD2;

FIG. 66 is a schematic cross-sectional view illustrating a configuration of a part of a semiconductor memory device according to another embodiment;

FIG. 67 is a schematic cross-sectional view illustrating a configuration of a part of a semiconductor memory device according to another embodiment;

FIG. 68 is a schematic cross-sectional view illustrating a configuration of a part of a semiconductor memory device according to another embodiment;

FIG. 69 is a schematic cross-sectional view illustrating a configuration of a part of a semiconductor memory device according to another embodiment; and

FIG. 70 is a schematic cross-sectional view illustrating a configuration of a part of a semiconductor memory device according to another embodiment.

### DETAILED DESCRIPTION

A semiconductor memory device according to one embodiment comprises: a first memory plane region including a plurality of memory finger structures extending in a first direction and arranged in a second direction intersecting with the first direction; and a kerf region arranged in the first direction with the first memory plane region and extending in the second direction. The plurality of memory finger structures include: a first stacked body including a plurality of first conductive layers stacked in a stacking direction intersecting with the first direction and the second direction; a plurality of semiconductor columns extending in the stacking direction and opposed to the plurality of first conductive layers; a plurality of electric charge accumulating films disposed between the plurality of first conductive layers and the plurality of semiconductor columns; and a plurality of first terrace portions disposed at end portions on a kerf region side in the first direction of the plurality of first conductive layers. The kerf region includes a second stacked body including a plurality of first layers stacked in the stacking direction corresponding to at least a part of the plurality of first conductive layers. The second stacked body is spaced in the first direction from the first stacked body. A first region in the kerf region is arranged in the first direction with a part of the plurality of memory finger structures and includes a part of the second stacked body. A second region in the kerf region is arranged in the first direction with another part of the plurality of memory finger structures, is arranged in the second direction with the first region in the kerf region, and does not include the second stacked body. A third region in the kerf region extends in the second direction along an end portion on a first memory plane region side in the first direction of the kerf region, is arranged in the first direction with the first region and the second region, and includes another part of the second stacked body.

Next, the semiconductor memory devices according to embodiments are described in detail with reference to the drawings. The following embodiments are only examples, and not described for the purpose of limiting the present invention. The following drawings are schematic, and for convenience of description, apart of a configuration and the like is sometimes omitted. Parts common in a plurality of embodiments are attached by same reference numerals and their descriptions may be omitted.

In this specification, when referring to a “semiconductor memory device”, it may mean a memory die after dicing and may mean a memory wafer before dicing. In the former case, it may mean a memory die after packaging and may mean a memory die before packaging. In the latter case, a memory wafer may include a peripheral circuit and need not include a peripheral circuit.

In this specification, when it is referred that a first configuration “is electrically connected” to a second configuration, the first configuration may be directly connected to the second configuration, and the first configuration may be connected to the second configuration via a wiring, a semiconductor member, a transistor, or the like. For example, when three transistors are connected in series, even when the second transistor is in OFF state, the first transistor is “electrically connected” to the third transistor.

In this specification, when it is referred that the first configuration “is connected between” the second configuration and a third configuration, it may mean that the first configuration, the second configuration, and the third configuration are connected in series and the second configuration is connected to the third configuration via the first configuration.

In this specification, when it is referred that a circuit or the like “electrically conducts” two wirings or the like, it may mean, for example, that this circuit or the like includes a transistor or the like, this transistor or the like is disposed in a current path between the two wirings, and this transistor or the like is turned ON.

In this specification, a direction parallel to a surface of the substrate is referred to as an X-direction, a direction parallel to the surface of the substrate and perpendicular to the X-direction is referred to as a Y-direction, and a direction perpendicular to the surface of the substrate is referred to as a Z-direction.

In this specification, a direction along a predetermined plane is referred to as a first direction, a direction intersecting with the first direction along this predetermined plane is referred to as a second direction, and a direction intersecting with this predetermined plane is referred to as a third direction in some cases. These first direction, second direction, and third direction may correspond to any of the X-direction, the Y-direction, and the Z-direction and need not to correspond to these directions.

When expressions such as “above” and “below” are used in this specification, they are based on the substrate included in a memory die, a memory wafer, or the like. For example, a direction away from the substrate along the Z-direction may be referred to as above and a direction approaching the substrate along the Z-direction may be referred to as below. A lower surface and a lower end of a certain configuration may mean a surface and an end portion on a substrate side of this configuration. An upper surface and an upper end of a certain configuration may mean a surface and an end portion on a side opposite to the substrate of this configuration. A surface intersecting with the X-direction or the Y-direction may be referred to as a side surface and the like. The configurations described in the following embodiments are merely examples, and the vertical positional relation of the configurations described in the embodiments may be inverted.

In this specification, when referring to a “width”, a “length”, a “thickness”, or the like of a configuration, a member, or the like in a predetermined direction, this may mean a width, a length, a thickness, or the like in a cross-sectional surface or the like observed with a Scanning electron microscopy (SEM), a Transmission electron microscopy (TEM), or the like.

### First Embodiment

### Memory Die MD

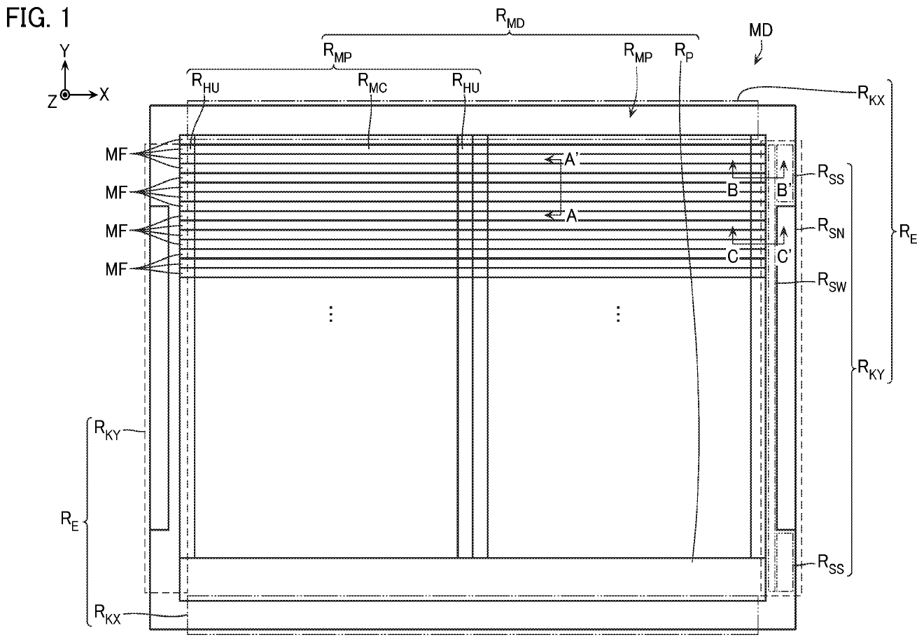

With reference to FIG. 1 to FIG. 4, an overall configuration of a memory die MD according to a first embodiment is described.

FIG. 1 is a schematic plan view illustrating the configuration of the memory die MD.

The memory die MD includes a memory region R_{MD}. The memory region R_{MD} includes two memory plane regions R_{MP} arranged in the X-direction and a peripheral region R_{P} disposed on one end side in the Y-direction with respect to the two memory plane regions R_{MP}. The memory plane region R_{MP} includes a plurality of memory finger structures MF arranged in the Y-direction and extending in the X-direction. The memory finger structure MF includes a memory cell region R_{MC} extending in the X-direction and hook-up regions R_{HU} disposed at both end portions in the X-direction of the memory cell region R_{MC}.

Further, the memory die MD includes an edge region R_{E} surrounding the memory region R_{MD}. The edge region R_{E} includes, for example, two kerf regions R_{KY} disposed at end portions on a positive side and a negative side in the X-direction of the memory die MD and extending in the Y-direction and two kerf regions R_{KX} disposed at end portions on a positive side and a negative side in the Y-direction of the memory die MD and extending in the X-direction.

The kerf region R_{KY} includes two stacked body regions R_{SS} arranged in the Y-direction and a non-stacked body region R_{SN} disposed between the two stacked body regions R_{SS}. The two stacked body regions R_{SS} and the non-stacked body region R_{SN} are each arranged in the X-direction with parts of the plurality of memory finger structures MF. Further, the kerf region R_{KY} includes a stacked body region R_{SW}. The stacked body region R_{SW} extends in the Y-direction along an end portion on the memory plane region R_{MP} side in the X-direction of the kerf region R_{KY} and along from one end to the other end in the Y-direction of the memory region R_{MD}. The stacked body region R_{SW} is arranged in the X-direction with the two stacked body regions R_{SS} and the non-stacked body region R_{SN}.

Note that configurations in the kerf regions R_{KY}, R_{KX} are not used for inputting/outputting a voltage or a signal to/from the memory finger structures MF.

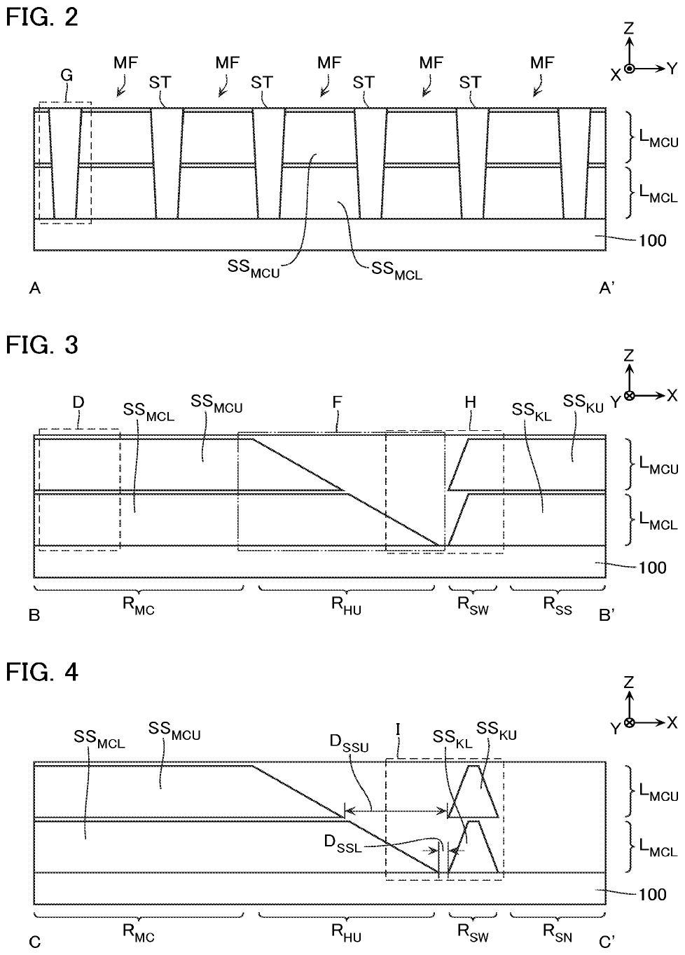

FIG. 2 to FIG. 4 are schematic cross-sectional views illustrating configurations of parts of the memory die MD. FIG. 2 illustrates a schematic cross-sectional surface of the structure illustrated in FIG. 1 taken along the line A-A′ and viewed along a direction of arrows. FIG. 3 illustrates a schematic cross-sectional surface of the structure illustrated in FIG. 1 taken along the line B-B′ and viewed along a direction of arrows. FIG. 4 illustrates a schematic cross-sectional surface of the structure illustrated in FIG. 1 taken along the line C-C′ and viewed along a direction of arrows.

As illustrated in FIG. 2 to FIG. 4, the memory die MD includes a conductive layer 100, a memory cell layer L_{MCL} disposed above the conductive layer 100, and a memory cell layer L_{MCU} disposed above the memory cell layer L_{MCL}.

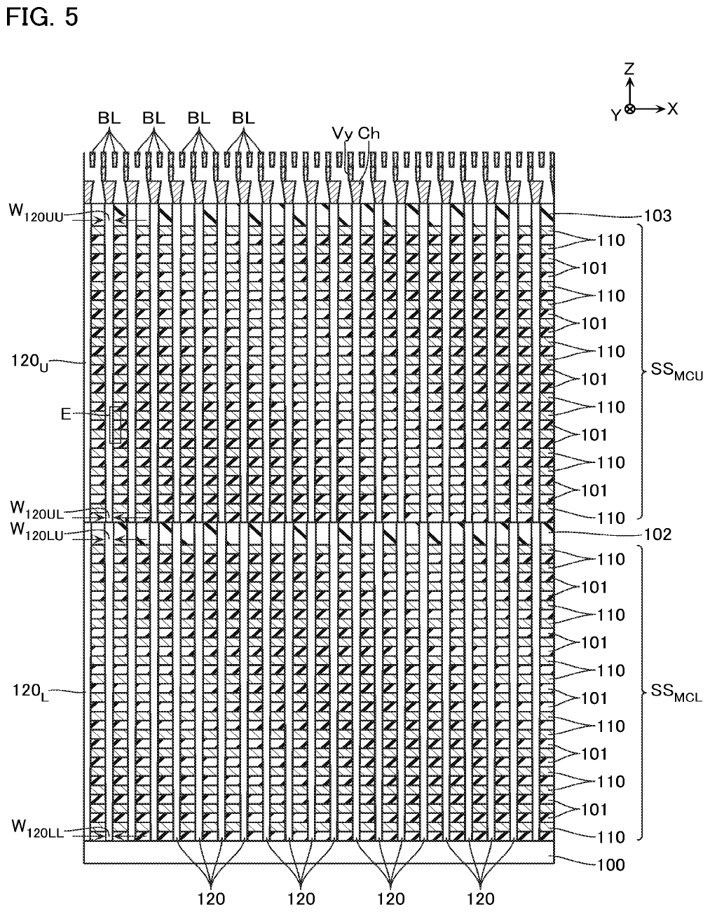

As illustrated in FIG. 2, the memory finger structure MF includes a stacked body SS_{MCL} disposed in the memory cell layer L_{MCL} and a stacked body SS_{MCU} disposed in the memory cell layer L_{MCU}. As described in detail later, the stacked bodies SS_{MCL}, SS_{MCU} include a plurality of conductive layers 110 (FIG. 5) stacked in the Z-direction. An inter-finger structure ST is disposed between two memory finger structures MF adjacent in the Y-direction. As illustrated in FIG. 3, the stacked bodies SS_{MCL}, SS_{MCU} extend in the X-direction. Both end portions in the X-direction of the stacked bodies SS_{MCL}, SS_{MCU} are disposed in the two hook-up regions R_{HU} (FIG. 1) arranged in the X-direction.

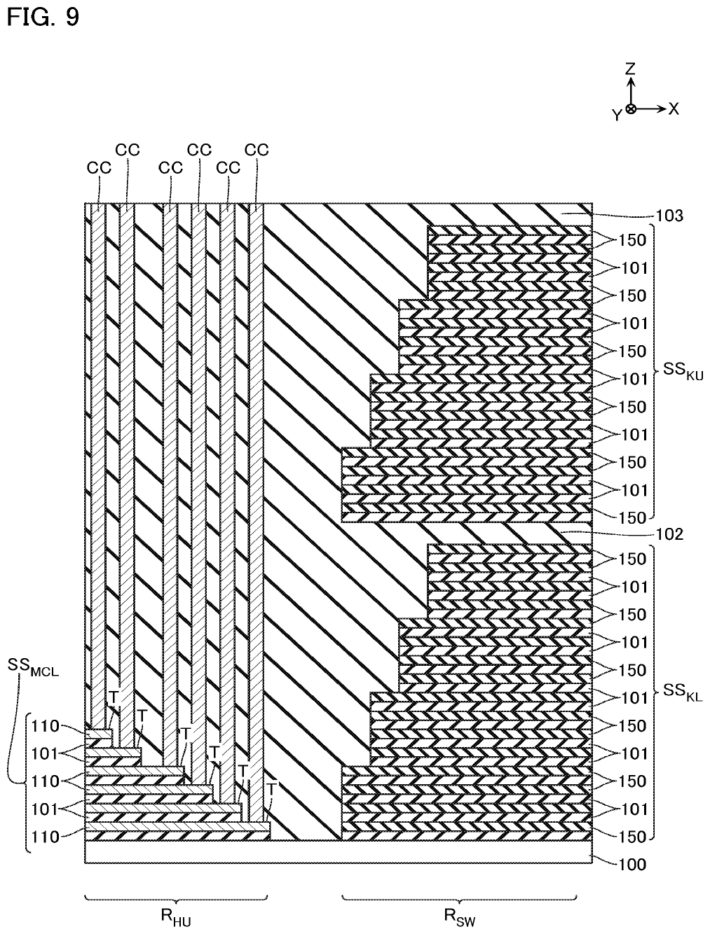

As illustrated in FIG. 3, the stacked body regions R_{SS}, R_{SW} each include a part of a stacked body SS_{KL} disposed in the memory cell layer L_{MCL} and a part of a stacked body SS_{KU} disposed in the memory cell layer L_{MCU}. As described in detail later, the stacked bodies SS_{KL}, SS_{KU} include a plurality of layers 150 (FIG. 9) stacked in the Z-direction corresponding to at least a part of the plurality of conductive layers 110. As illustrated in FIG. 4, the non-stacked body region R_{SN} does not include the stacked bodies SS_{KL}, SS_{KU}.

As illustrated in FIG. 3 and FIG. 4, the stacked bodies SS_{KL}, SS_{KU} disposed in the stacked body region R_{SW} are spaced in the X-direction from the stacked bodies SS_{MCL}, SS_{MCU} disposed in the hook-up region R_{HU}. Other stacked bodies and the like are not disposed between the stacked bodies SS_{KL}, SS_{KU} disposed in the stacked body region R_{SW} and the stacked bodies SS_{MCL}, SS_{MCU} disposed in the hook-up region R_{HU}.

A distance D_{SSL} (FIG. 4) in the X-direction between the stacked body SS_{MCL} and the stacked body SS_{KL} is approximately constant from one end to the other end in the Y-direction of the memory plane region R_{MP} (FIG. 1). That is, the distance D_{SSL} is approximately constant from one end to the other end in the Y-direction of the plurality of memory finger structures MF (FIG. 1) arranged in the Y-direction. Note that the distance D_{SSL} in the X-direction between the stacked body SS_{MCL} and the stacked body SS_{KL} may be, for example, a distance in the X-direction between a lowermost conductive layer 110 of those included in the stacked body SS_{MCL} (a conductive layer 110 closest to the conductive layer 100) and a lowermost layer 150 of those included in the stacked body SS_{KL} (a layer 150 closest to the conductive layer 100).

A distance D_{SSU} (FIG. 4) in the X-direction between the stacked body SS_{MCU} and the stacked body SS_{KU} is approximately constant from one end to the other end in the Y-direction of the memory plane region R_{MP} (FIG. 1). That is, the distance D_{SSU} is approximately constant from one end to the other end in the Y-direction of the plurality of memory finger structures MF (FIG. 1) arranged in the Y-direction. The distance D_{SSU} is greater than the distance D_{SSL}. Note that the distance D_{SSU} in the X-direction between the stacked body SS_{MCU} and the stacked body SS_{KU} may be, for example, a distance in the X-direction between a lowermost conductive layer 110 of those included in the stacked body SS_{MCU} (a conductive layer 110 closest to the conductive layer 100) and a lowermost layer 150 of those included in the stacked body SS_{KU} (a layer 150 closest to the conductive layer 100).

[Memory Cell Region R_{MC}]

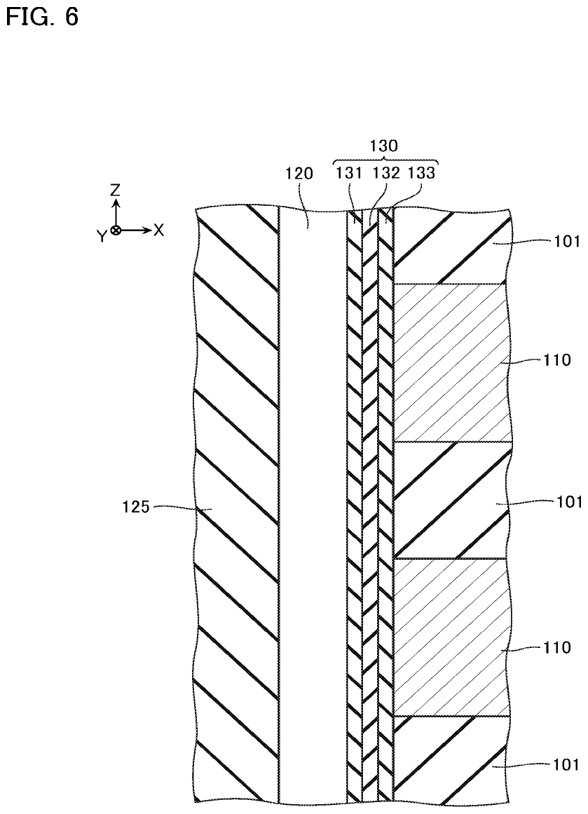

Next, with reference to FIG. 5 and FIG. 6, a configuration of the memory cell region R_{MC} is described. FIG. 5 and FIG. 6 are schematic cross-sectional views illustrating a configuration of a part of the memory cell region R_{MC}. FIG. 5 illustrates an enlarged part indicated by D in FIG. 3. FIG. 6 illustrates an enlarged part indicated by E in FIG. 5. While FIG. 6 illustrates an XZ cross-sectional surface, a structure similar to FIG. 6 is also observed when a cross-sectional surface (for example, a YZ cross-sectional surface) other than the XZ cross-sectional surface along the central axis of a semiconductor column 120 is observed.

As described with reference to FIG. 2, the memory finger structure MF includes the stacked body SS_{MCL} and the stacked body SS_{MCU}. The stacked bodies SS_{MCL}, SS_{MCU} each include the plurality of conductive layers 110 stacked in the Z-direction and a plurality of interlayer insulating layers 101 disposed between each two of the plurality of conductive layers 110. In the memory cell region R_{MC}, the memory finger structure MF includes a plurality of semiconductor columns 120 extending in the Z-direction and a respective plurality of gate insulating films 130 (FIG. 6) disposed between the plurality of conductive layers 110 and the plurality of semiconductor columns 120. An insulating layer 102 of silicon oxide (SiO₂) or the like is disposed between the stacked bodies SS_{MCL}, SS_{MCU}. An insulating layer 103 of silicon oxide (SiO₂) or the like is disposed on an upper surface of the stacked body SS_{MCU}.

The conductive layer 110 has an approximately plate shape extending in the X-direction. The conductive layer 110 may include, for example, a stacked film of a barrier conductive film of titanium nitride (TiN) or the like and a metal film of tungsten (W) or the like. The conductive layer 110 may contain, for example, polycrystalline silicon containing impurities, such as phosphorus (P) or boron (B).

Among the plurality of conductive layers 110, one or a plurality of conductive layers 110 positioned at the lowermost layer function as a select gate line and gate electrodes of a plurality of select transistors connected to the select gate line of a NAND flash memory. These plurality of conductive layers 110 are electrically independent for each memory block of the NAND flash memory.

A plurality of conductive layers 110 positioned above these conductive layers 110 function as word lines and gate electrodes of a plurality of memory cells (memory transistors) connected to the word lines of the NAND flash memory. These plurality of conductive layers 110 are each electrically independent for each memory block of the NAND flash memory.

Further, one or a plurality of conductive layers 110 positioned above these conductive layers 110 function as select gate lines and gate electrodes of a plurality of select transistors connected to the select gate lines of the NAND flash memory. These plurality of conductive layers 110 may each be electrically independent for each unit smaller than the memory block of the NAND flash memory.

The interlayer insulating layer 101 contains, for example, silicon oxide (SiO₂) or the like.

The semiconductor columns 120 are arranged in a predetermined pattern in the X-direction and the Y-direction. The semiconductor columns 120 function as channel regions of the memory cells of the NAND flash memory and channel regions of the select transistors of the NAND flash memory. The semiconductor column 120 contains, for example, polycrystalline silicon (Si) or the like. The semiconductor column 120 has an approximately cylindrical shape, and includes an insulating column 125 (FIG. 6) of silicon oxide or the like in the center portion.

As illustrated in FIG. 5, the semiconductor column 120 includes a semiconductor region 120_{L} opposed to the conductive layers 110 in the stacked body SS_{MCL} and a semiconductor region 120_{U} opposed to the conductive layers 110 in the stacked body SS_{MCU}.

The semiconductor region 120_{L} has an approximately cylindrical shape extending in the Z-direction. The semiconductor region 120_{L} has an outer peripheral surface surrounded by the plurality of conductive layers 110 each in the stacked body SS_{MCL}. Note that a width W_{120LL} in a radial direction of a lower end portion of the semiconductor region 120_{L} is smaller than a width W_{120LU} in the radial direction of an upper end portion of the semiconductor region 120_{L}.

The semiconductor region 120_{L} has a lower end connected to the above-mentioned conductive layer 100. The lower end of the semiconductor region 120_{L} contains, for example, N-type impurities, such as phosphorus (P), or P-type impurities, such as boron (B). The conductive layer 100 functions as, for example, a part of a source line of the NAND flash memory. The conductive layer 100 contains, for example, polycrystalline silicon (Si) containing N-type impurities, such as phosphorus (P), or P-type impurities, such as boron (B).

The semiconductor region 120_{U} has an approximately cylindrical shape extending in the Z-direction. The semiconductor region 120_{U} has an outer peripheral surface surrounded by the plurality of conductive layers 110 each in the stacked body SS_{MCU}. Note that a width W_{120UL} in the radial direction of a lower end portion of the semiconductor region 120_{U} is smaller than a width W_{120UU} in the radial direction of an upper end portion of the semiconductor region 120_{U} and the above-mentioned width W_{120LU}.

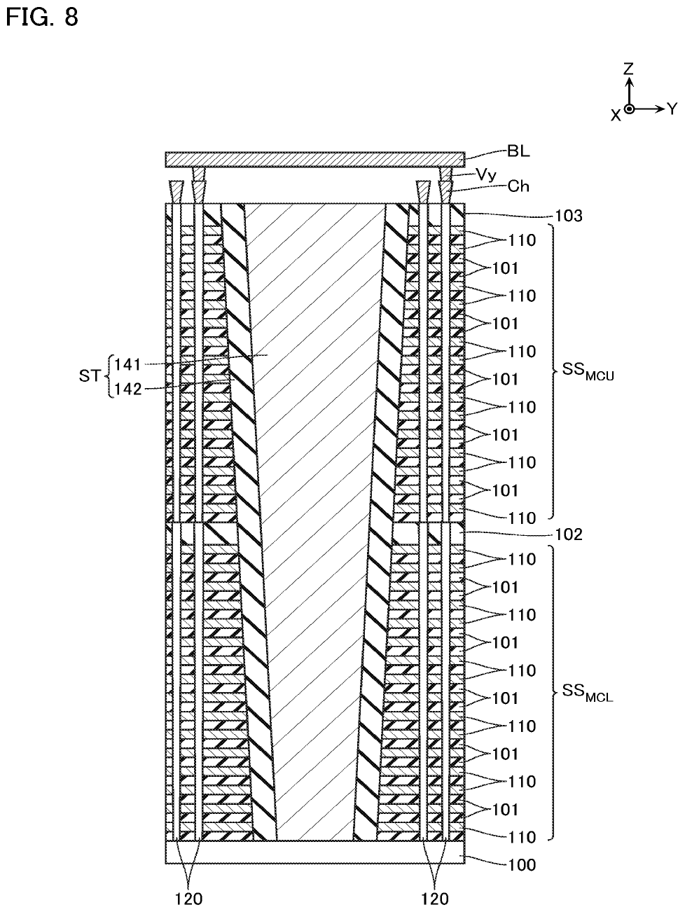

The semiconductor region 120_{U} has an upper end containing, for example, N-type impurities, such as phosphorus (P). The upper end of the semiconductor region 120_{U} is electrically connected to a bit line BL via a via-contact electrode Ch and a via-contact electrode Vy. The bit lines BL are arranged in the X-direction and extend in the Y-direction (see FIG. 8).

The gate insulating film 130 (FIG. 6) has an approximately cylindrical shape that covers an outer peripheral surface of the semiconductor column 120. The gate insulating film 130 includes, for example, a tunnel insulating film 131, an electric charge accumulating film 132, and a block insulating film 133, which are stacked between the semiconductor column 120 and the conductive layers 110. The tunnel insulating film 131 and the block insulating film 133 contain, for example, silicon oxide (SiO₂) or the like. The electric charge accumulating film 132 includes, for example, a film configured to accumulate electric charges of silicon nitride (SiN) or the like. The tunnel insulating film 131, the electric charge accumulating film 132, and the block insulating film 133, which have approximately cylindrical shapes, extend in the Z-direction along the outer peripheral surface of the semiconductor column 120 excluding a contact portion of the semiconductor column 120 and the conductive layer 100 (FIG. 5).

FIG. 6 illustrates an example in which the gate insulating film 130 includes the electric charge accumulating film 132 of silicon nitride or the like. However, the gate insulating film 130 may include, for example, a floating gate of polycrystalline silicon containing N-type or P-type impurities or the like.

[Hook-Up Region R_{HU}]

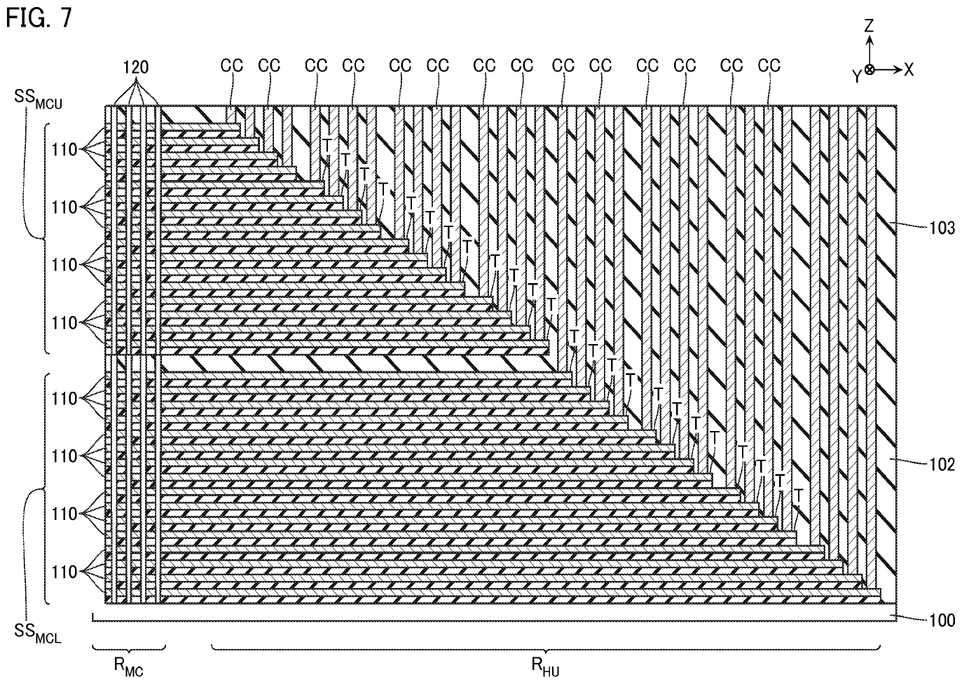

Next, with reference to FIG. 7, a configuration of the hook-up region R_{HU} is described. FIG. 7 is a schematic cross-sectional view illustrating a configuration of a part of the hook-up region R_{HU}. FIG. 7 illustrates an enlarged part indicated by F in FIG. 3.

The hook-up region R_{HU} includes end portions in the X-direction of the plurality of conductive layers 110 and terrace portions T. The terrace portion T is a part of an upper surface of the conductive layer 110 disposed at a position that does not overlap with other conductive layers 110 when viewed from above. The insulating layer 102 is disposed above the terrace portions T of the plurality of conductive layers 110 included in the stacked body SS_{MCL}. The insulating layer 103 is disposed above the terrace portions T of the plurality of conductive layers 110 included in the stacked body SS_{MCU}.

Further, the hook-up region R_{HU} includes a plurality of via-contact electrodes CC corresponding to the plurality of terrace portions T. The via-contact electrode CC extends in the Z-direction and has a lower end connected to the terrace portion T of the conductive layer 110. The via-contact electrode CC may include, for example, a stacked film of a barrier conductive film of titanium nitride (TiN) or the like and a metal film of tungsten (W) or the like.

[Inter-Finger Structure ST]

Next, with reference to FIG. 8, a configuration of the inter-finger structure ST is described. FIG. 8 is a schematic cross-sectional view illustrating a configuration of a part of the inter-finger structure ST. FIG. 8 illustrates an enlarged part indicated by G in FIG. 2.

The inter-finger structure ST includes, as illustrated in FIG. 8, for example, a conductive member 141 extending in the Z-direction and insulating members 142 disposed on side surfaces of the conductive member 141. The conductive member 141 has a lower end contacted to the conductive layer 100. The conductive member 141 may include, for example, a stacked film of a barrier conductive film of titanium nitride (TiN) or the like and a metal film of tungsten (W) or the like. The conductive member 141 functions as, for example, a part of the source line of the NAND flash memory. Note that the inter-finger structure ST need not include a conductive member.

[Edge Region R_{E}]

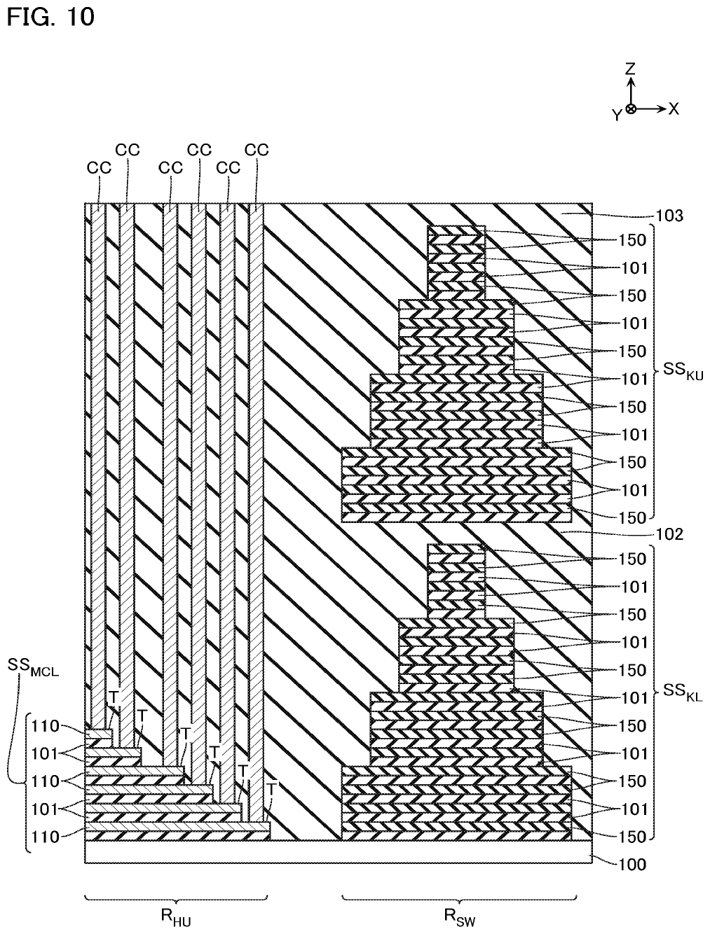

Next, with reference to FIG. 9 and FIG. 10, a configuration of the edge region R_{E} is described. FIGS. 9 and FIG. 10 are schematic cross-sectional views illustrating a configuration of a part of the edge region R_{E}. FIG. 9 illustrates an enlarged part indicated by H in FIG. 3. FIG. 10 illustrates an enlarged part indicated by I in FIG. 4.

As described with reference to FIG. 3, the stacked body regions R_{SS}, R_{SW} in the edge region R_{E} include a part of the stacked body SS_{KL} disposed in the memory cell layer L_{MCL} and a part of the stacked body SS_{KU} disposed in the memory cell layer L_{MCU}. The stacked bodies SS_{KL}, SS_{KU} include the plurality of layers 150 stacked in the Z-direction corresponding to at least a part of the conductive layers 110 (FIG. 5) and the plurality of interlayer insulating layers 101 disposed between each two of the plurality of layers 150.

A configuration of the layer 150 is appropriately adjustable. The layer 150 may include an insulating layer of silicon nitride (SiN) or the like, may include a conductive layer containing a material similar to that of the conductive layer 110, or may include both.

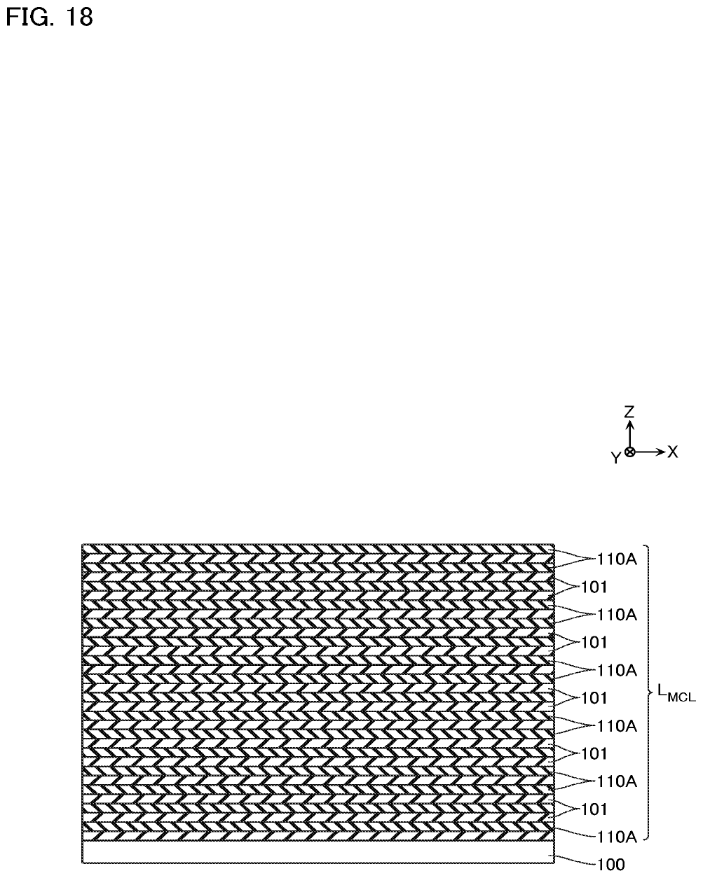

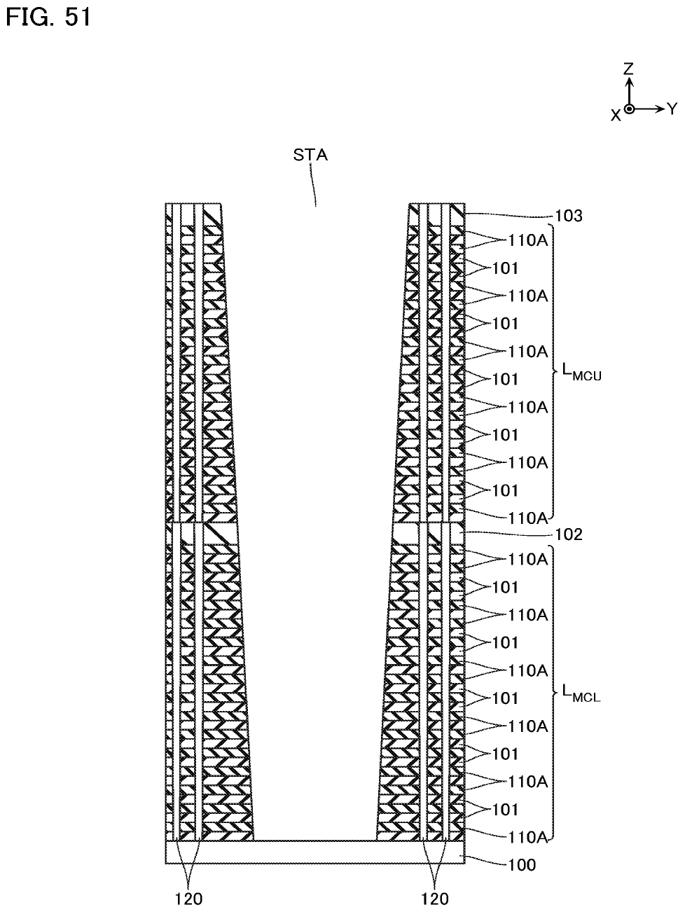

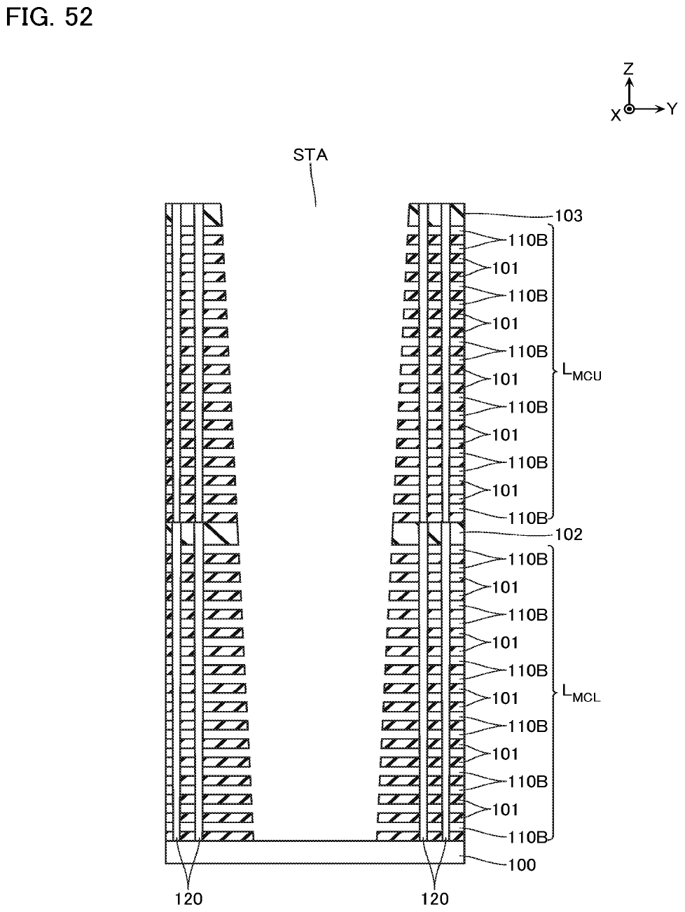

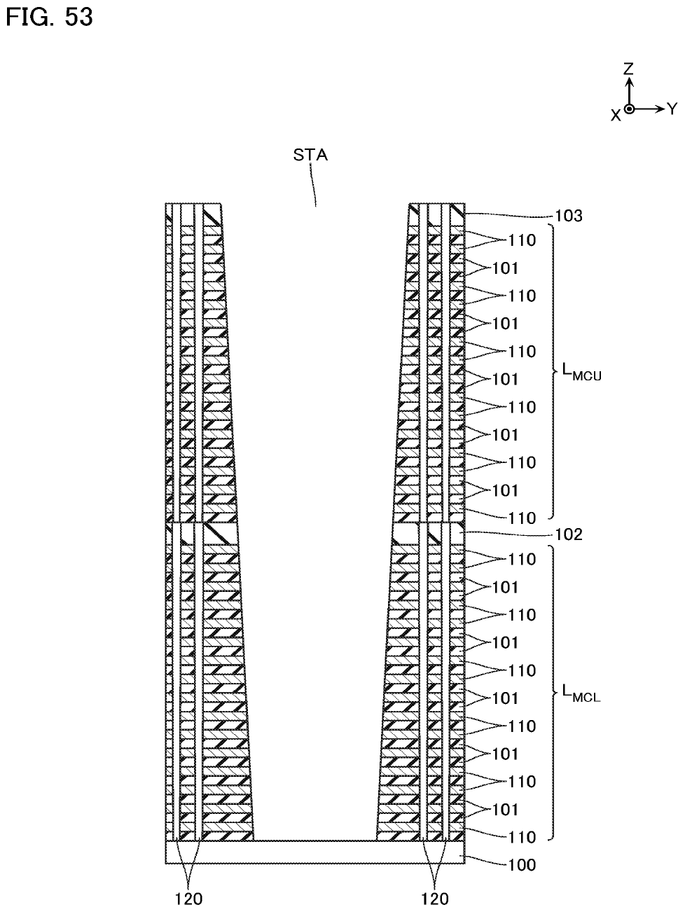

For example, as described in detail later, sacrifice layers 110A (FIG. 18) of silicon nitride (SiN) or the like can be used to form the stacked bodies SS_{MCL}, SS_{MCU} described with reference to FIG. 5. For example, the interlayer insulating layers 101 and the sacrifice layers 110A are stacked in alternation. Further, a trench STA corresponding to the inter-finger structure ST described with reference to FIG. 8 is formed (FIG. 51), the sacrifice layers 110A are removed via the trench STA (FIG. 52), and the conductive layers 110 of tungsten (W) or the like are formed there (FIG. 53). When such a method is employed, for example, the layer 150 may contain a conductive material, such as titanium nitride (TiN) and tungsten (W), similarly to the conductive layer 110 at the proximity of a structure similar to the inter-finger structure ST in the stacked body regions R_{SS}, R_{SW}. In other regions, the layer 150 may contain an insulating material of silicon nitride (SiN) or the like, similarly to the sacrifice layer 110A.

When, for example, sacrifice layers are not used to form the stacked bodies SS_{MCL}, SS_{MCU}, the layer 150 may contain a material similar to that of the conductive layer 110. For example, the layer 150 and the conductive layer 110 may contain polycrystalline silicon or the like containing impurities, such as phosphorus (P) or boron (B).

[Memory Wafer MW]

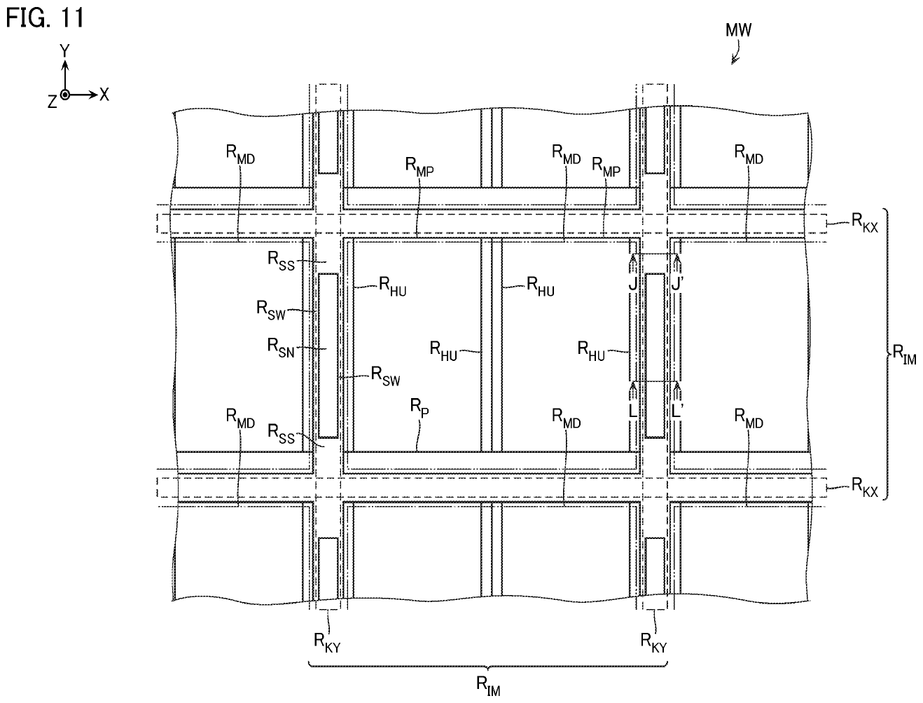

Next, with reference to FIG. 11 to FIG. 17, a configuration of a memory wafer MW according to the first embodiment is described.

FIG. 11 is a schematic plan view illustrating a configuration of a part of the memory wafer MW.

The memory wafer MW includes a plurality of memory regions R_{MD} arranged in the X-direction and the Y-direction and an inter-memory region R_{IM} disposed between these plurality of memory regions R_{MD}. The inter-memory region R_{IM} includes a plurality of kerf regions R_{KX} extending in the X-direction and arranged in the Y-direction and a plurality of kerf regions R_{KY} extending in the Y-direction and arranged in the X-direction. The memory die MD described with reference to FIG. 1 is formed by dicing the memory wafer MW along dicing lines in the inter-memory regions R_{IM}. The kerf regions R_{KY}, R_{KX} described with reference to FIG. 1 are parts of the kerf regions R_{KY}, R_{KX} illustrated in FIG. 11.

The kerf regions R_{KY}, R_{XX} include various kinds of regions used to manufacture the memory wafer MW. Examples of such regions include, for example, a marked region used for positioning in patterning of each configuration, a monitoring region used for monitoring shapes of via holes and trenches in processing, such as etching, and a film thickness measurement region for measuring a film thickness in film forming of each configuration.

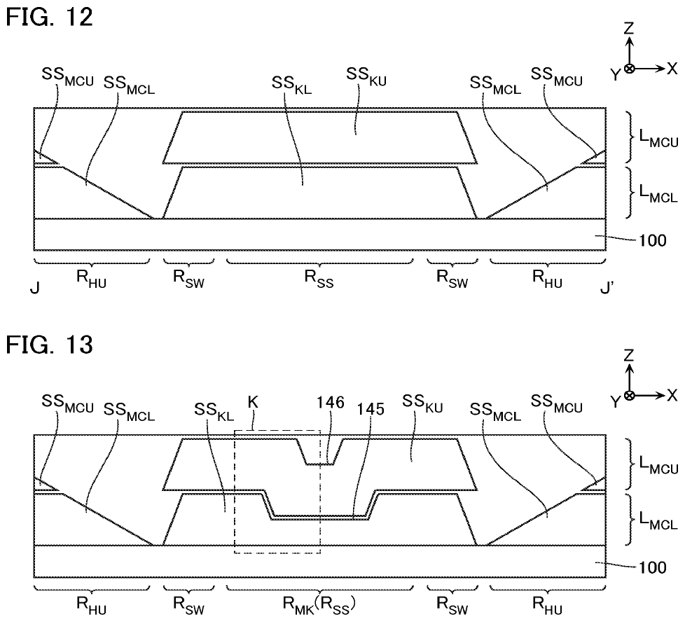

FIG. 12 is a schematic cross-sectional view illustrating a configuration of a part of the memory wafer MW. FIG. 12 illustrates a schematic cross-sectional surface of the structure illustrated in FIG. 11 taken along the line J-J′ and viewed along a direction of arrows.

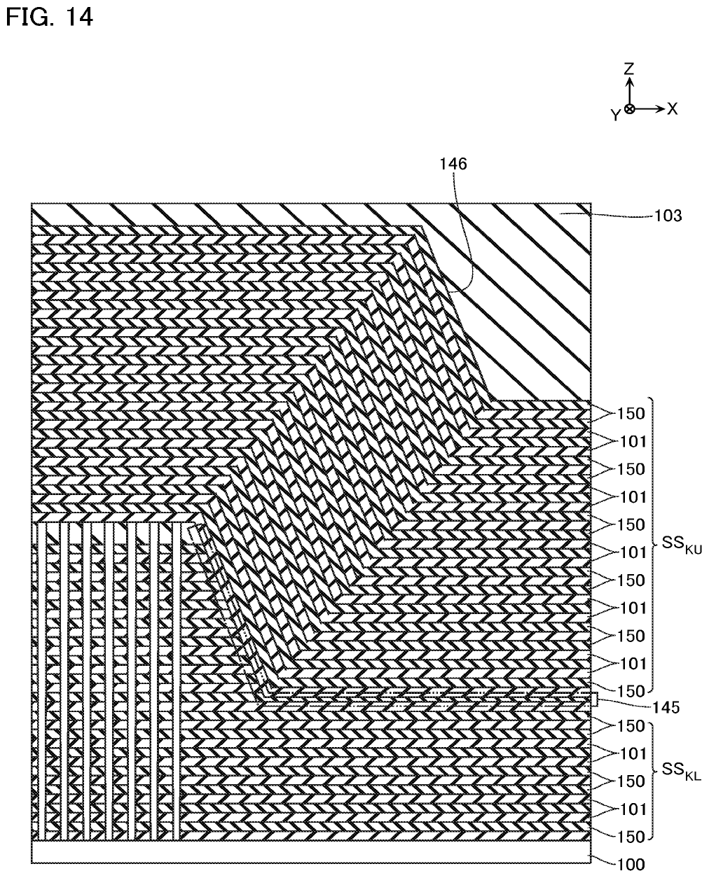

As described above, configurations in the kerf regions R_{KY}, R_{KX} are not used for inputting/outputting a voltage or a signal to/from the memory finger structures MF. That is, the configuration in the stacked body region R_{SS} is not used for inputting/outputting a voltage or a signal to/from the memory finger structures MF. The stacked body region R_{SS} includes various kinds of regions used to manufacture the memory wafer MW. FIG. 13 and FIG. 14 are schematic cross-sectional views exemplifying the configuration in the stacked body region R_{SS}. FIG. 14 illustrates an enlarged part indicated by K in FIG. 13.

FIG. 13 and FIG. 14 exemplify a marked region R_{MK} as an example. Here, as described with reference to FIG. 5, the semiconductor column 120 includes the semiconductor region 120_{L} opposed to the conductive layers 110 in the stacked body SS_{MCL} and the semiconductor region 120_{U} opposed to the conductive layers 110 in the stacked body SS_{MCU}. As described in detail later, the marked region R_{MK} is used as a reference indicating a position of the semiconductor region 120_{L} to position the semiconductor region 120_{U}.

As illustrated in FIG. 14, in the marked region R_{MK}, parts of the layers 150 and the interlayer insulating layers 101 disposed on an upper side in the stacked body SS_{KL} are removed, thereby forming a recessed portion 145 on an upper surface of the stacked body SS_{KL}. Further, in the marked region R_{MK}, the plurality of layers 150 and the interlayer insulating layers 101 in the stacked body SS_{KU} are formed along the recessed portion 145, thereby forming a recessed portion 146 on an upper surface of the stacked body SS_{KU}. The recessed portion 146 is used as a reference indicating a position of the semiconductor region 120_{L} to position the semiconductor region 120_{U}.

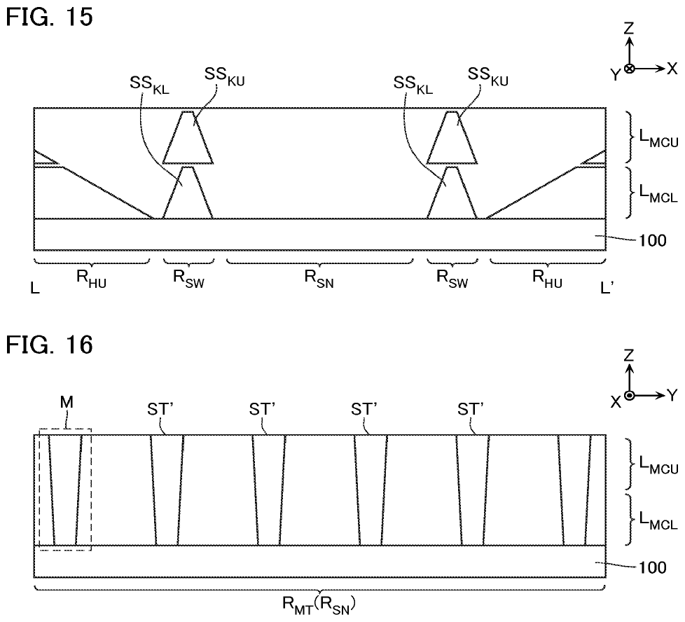

FIG. 15 is a schematic cross-sectional view illustrating a configuration of a part of the memory wafer MW. FIG. 15 illustrates a schematic cross-sectional surface of the structure illustrated in FIG. 11 taken along the line L-L′ and viewed along a direction of arrows.

Similarly to the configuration in the stacked body region R_{SS}, a configuration in the non-stacked body region R_{SN} is not used for inputting/outputting a voltage or a signal to/from the memory finger structures MF. The non-stacked body region R_{SN} includes various kinds of regions used to manufacture the memory wafer MW.

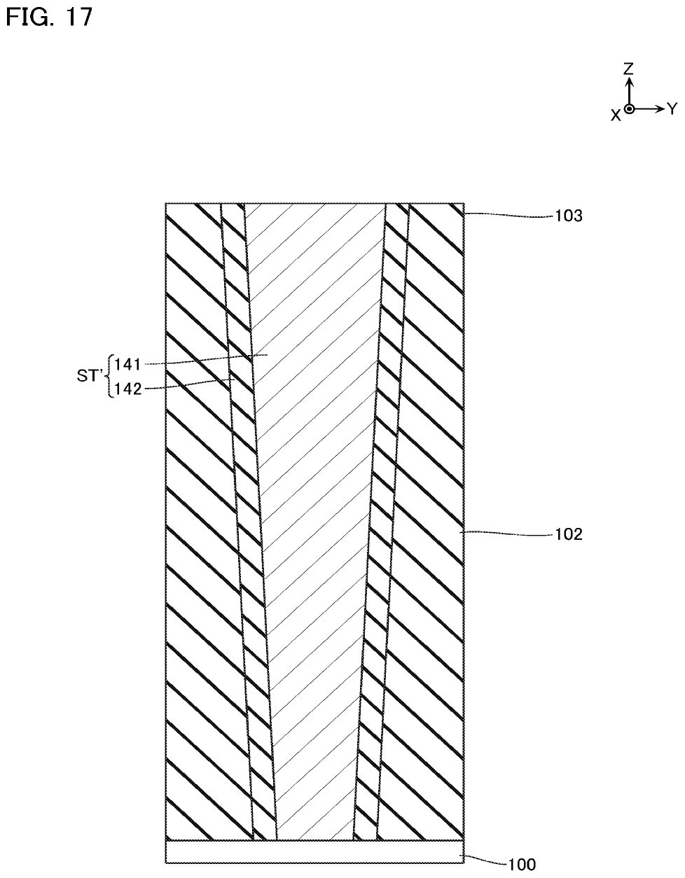

FIG. 16 and FIG. 17 are schematic cross-sectional views exemplifying the configuration in the non-stacked body region R_{SN}. FIG. 17 illustrates an enlarged part indicated by M in FIG. 16.

FIG. 16 and FIG. 17 exemplify a monitoring region R_{MT} as an example. The monitoring region R_{MT} is used for adjusting processing conditions in forming the trench STA (FIG. 51) corresponding to the inter-finger structure ST. As illustrated in FIG. 17, the monitoring region R_{MT} includes structures ST′ similar to the inter-finger structure ST.

[Manufacturing Method]

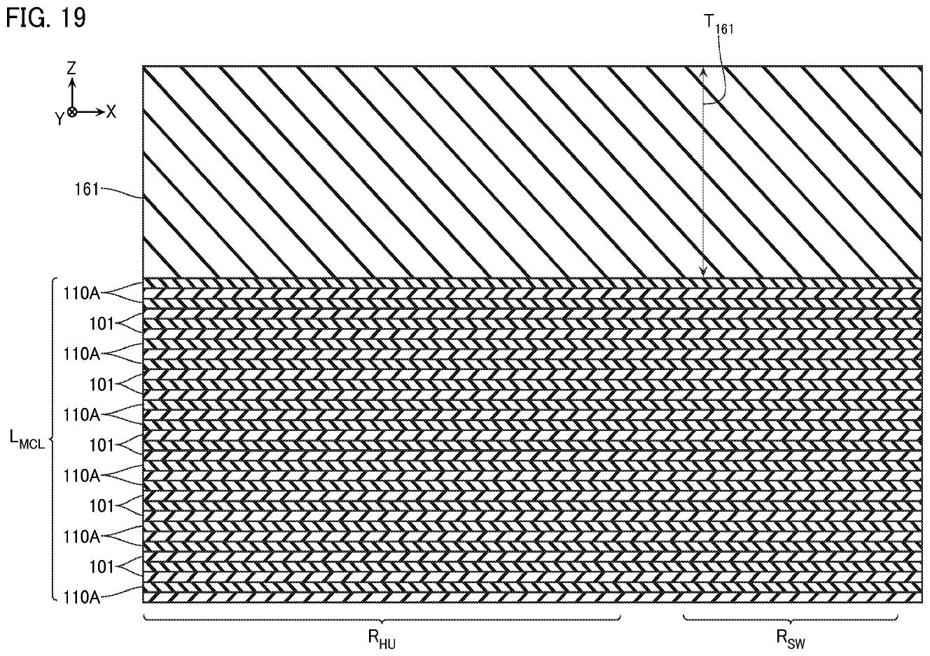

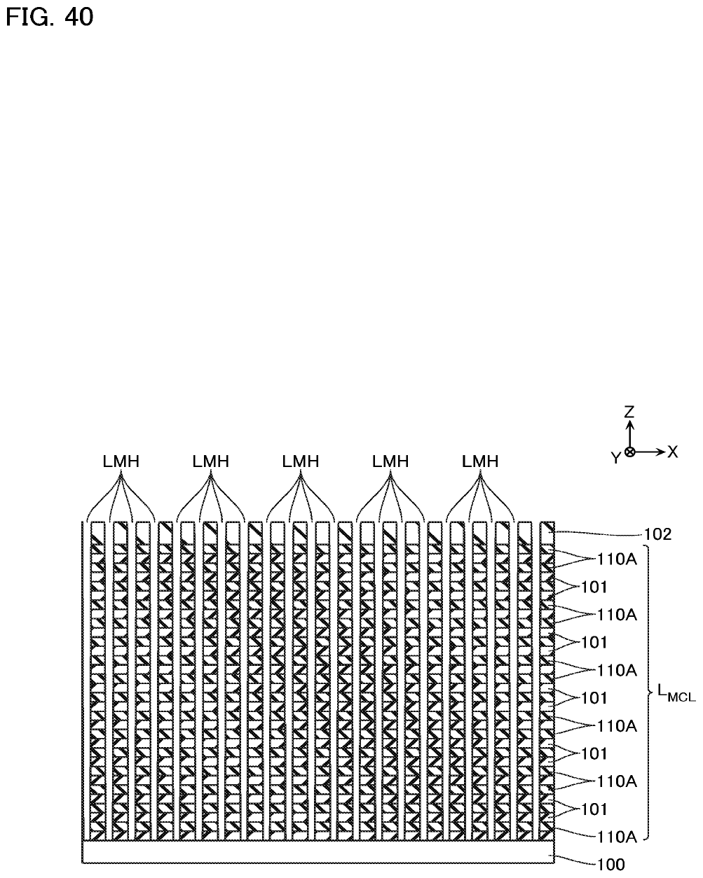

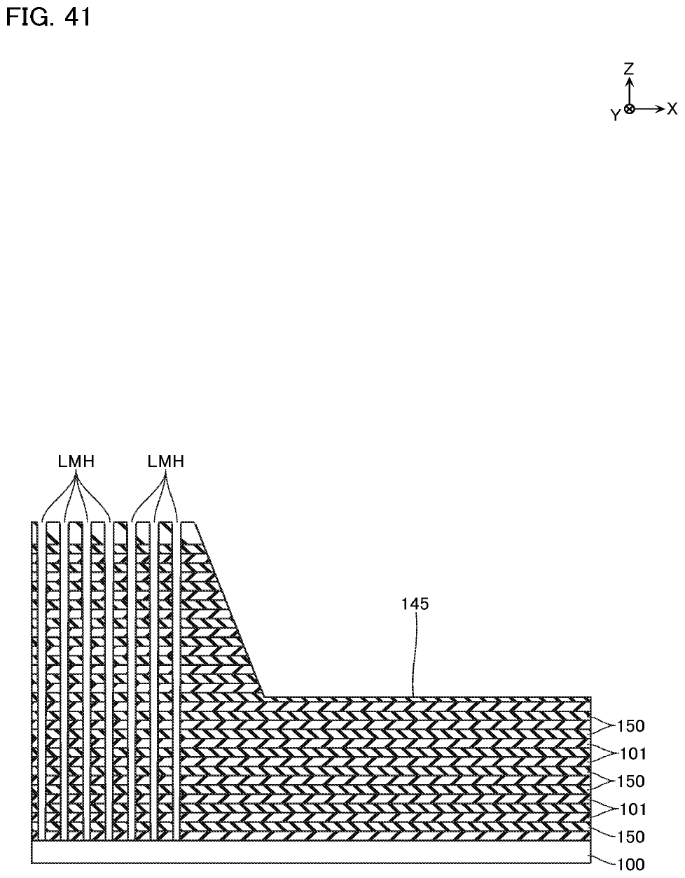

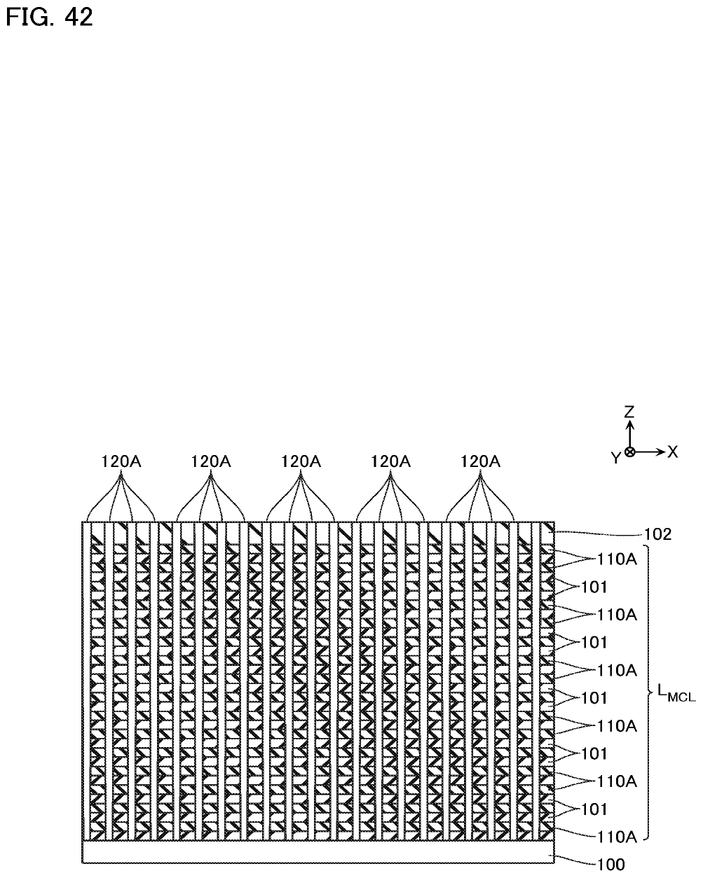

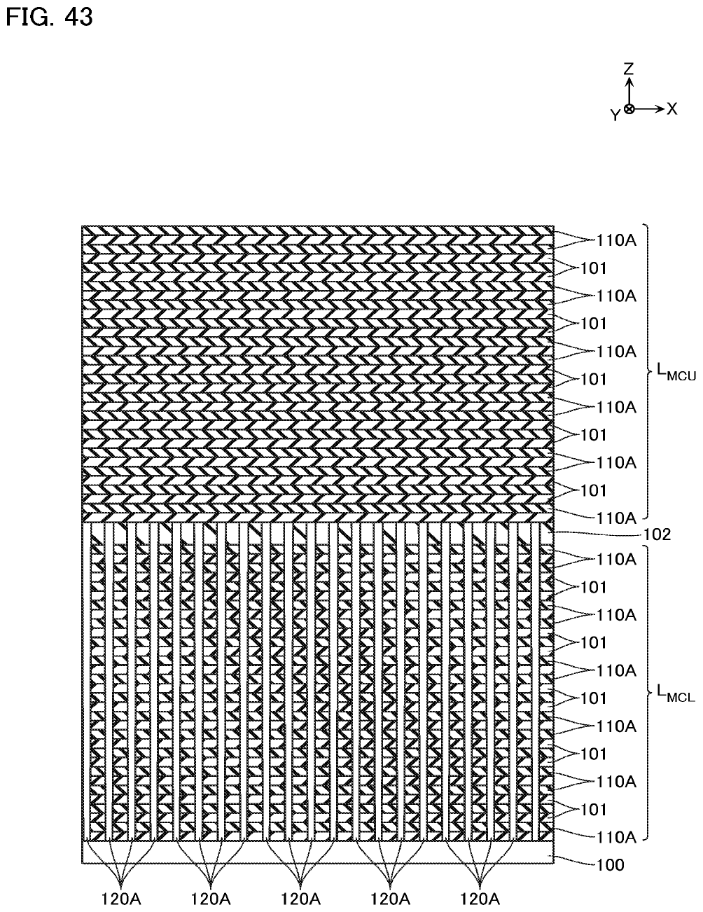

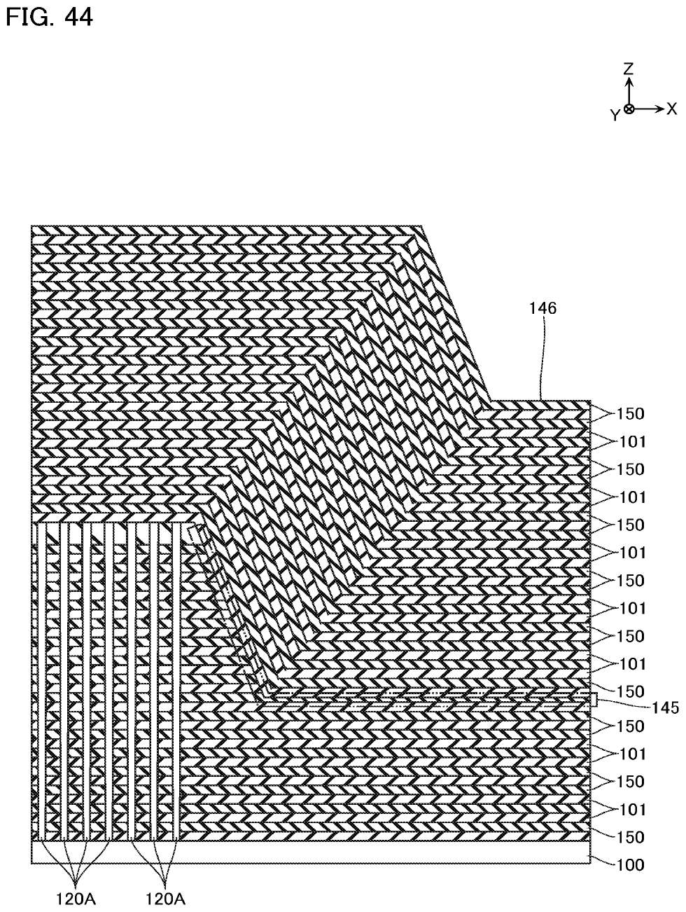

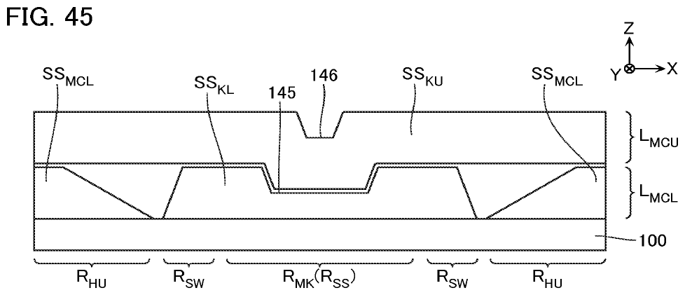

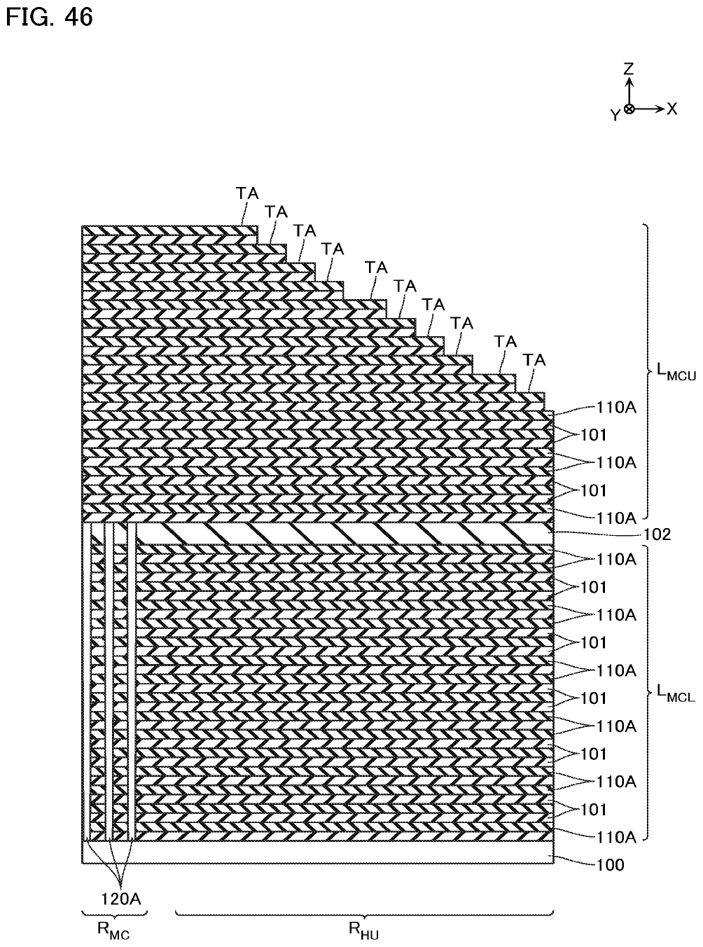

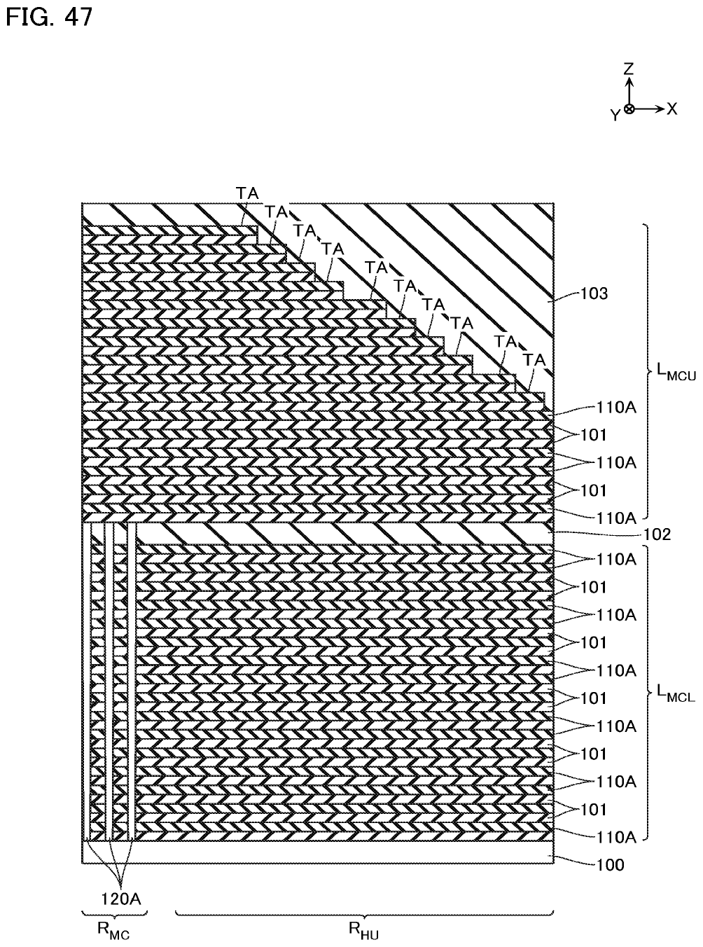

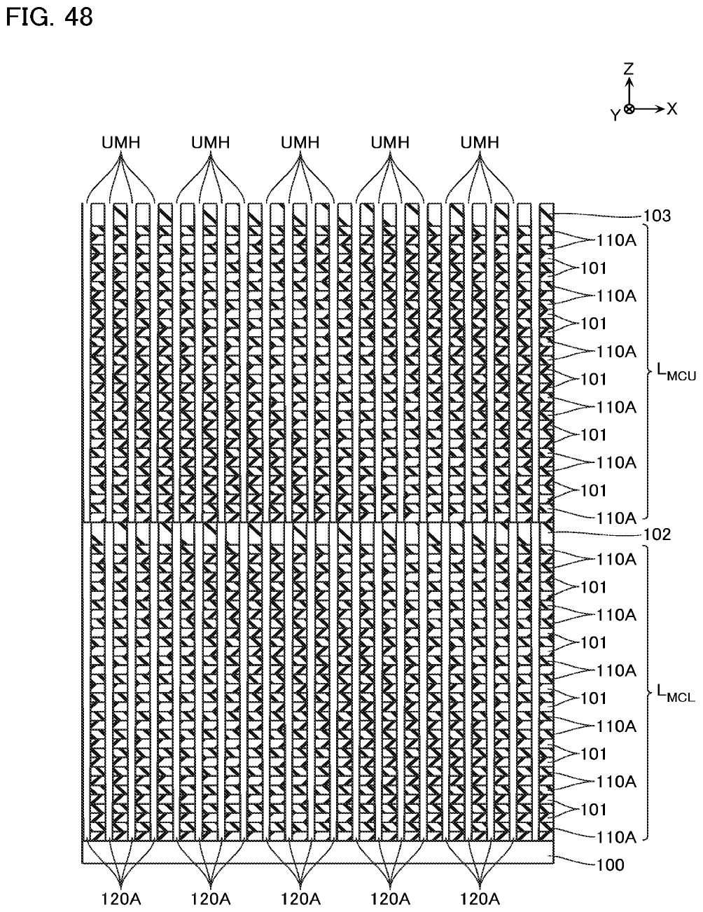

Next, with reference to FIG. 18 to FIG. 54, a method of manufacturing the memory die MD is described. FIG. 18 to FIG. 54 are schematic cross-sectional views for describing the manufacturing method. FIG. 18, FIG. 40, FIG. 42, FIG. 43, and FIG. 48 to FIG. 50 illustrate the cross-sectional surface corresponding to FIG. 5. FIG. 19 to FIG. 39 illustrate a cross-sectional surface corresponding to a part of the hook-up region R_{HU} and the stacked body region R_{SW}. FIG. 41 and FIG. 44 illustrate the cross-sectional surface corresponding to FIG. 14. FIG. 45 illustrates the cross-sectional surface corresponding to FIG. 13. FIG. 46 and FIG. 47 illustrate a cross-sectional surface corresponding to a part of the memory cell region R_{MC} and the hook-up region R_{HU}. FIG. 51 to FIG. 54 illustrate the cross-sectional surface corresponding to FIG. 8.

To manufacture the memory die MD according to the embodiment, as illustrated in FIG. 18, for example, the conductive layer 100 is formed above a substrate (not illustrated). Further, the plurality of interlayer insulating layers 101 and the plurality of sacrifice layers 110A are formed in alternation in the memory cell layer L_{MCL}. This process is performed by, for example, a method, such as Chemical Vapor Deposition (CVD).

Next, as illustrated in FIG. 19, a resist 161 is formed.

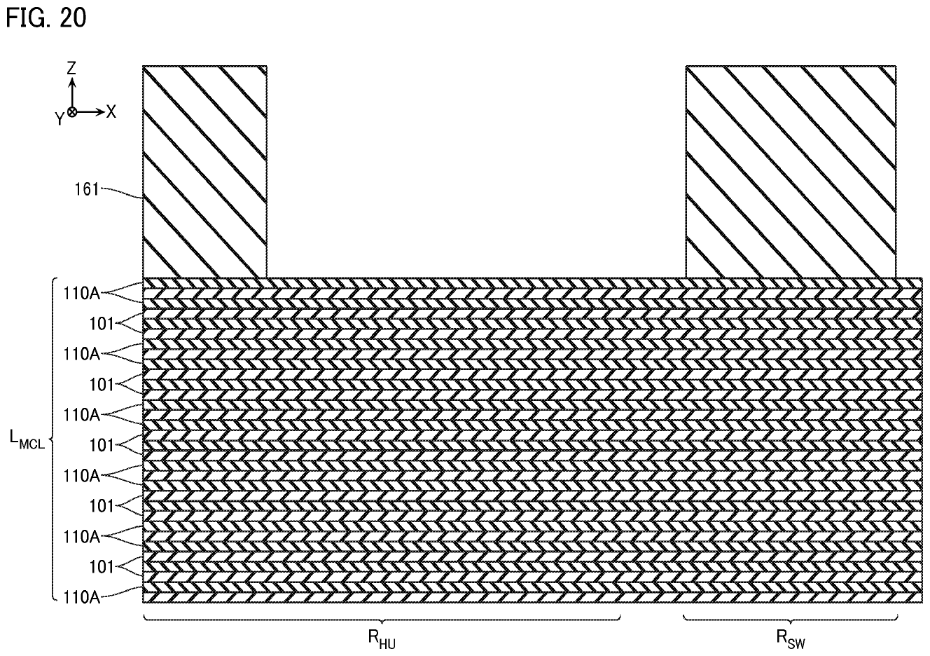

Next, as illustrated in FIG. 20, parts of the resist 161 is removed. After this process, the resist 161 covers the entire memory cell region R_{MC}. Further, in the hook-up region R_{HU}, the resist 161 covers a region corresponding to terrace portions T of a part of the conductive layers 110 (in the illustrated example, first to fourth conductive layers 110 counting from the upper side in the memory cell layer L_{MCL}) and exposes the other region. The resist 161 also covers the stacked body regions R_{SS}, R_{SW} in the inter-memory region R_{IM} and exposes the non-stacked body region R_{SN}.

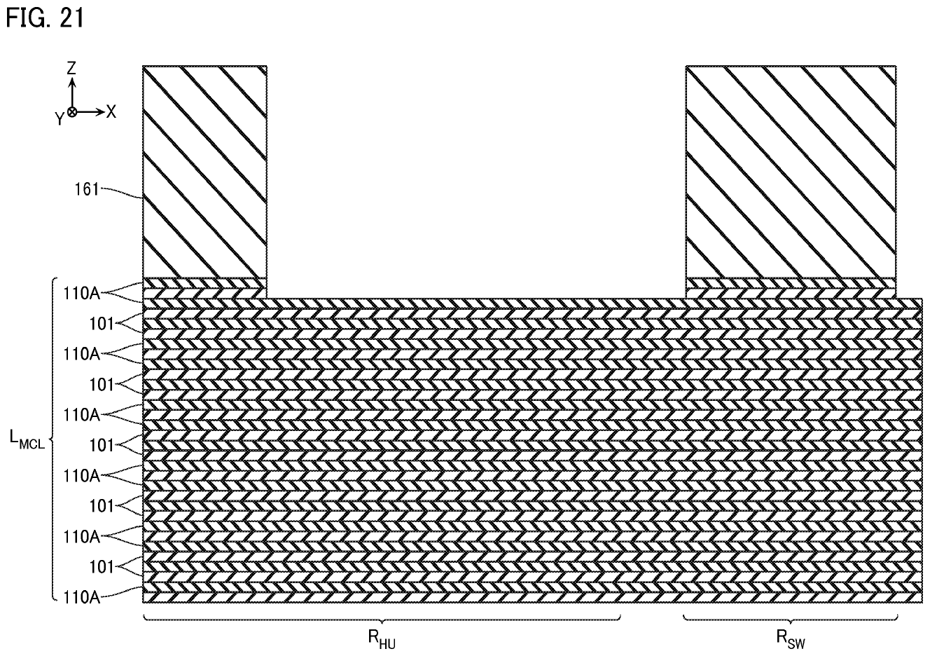

Next, as illustrated in FIG. 21, removal of the sacrifice layer 110A and removal of the interlayer insulating layer 101 are performed once for each. This process is performed by, for example, a method, such as wet etching or dry etching.

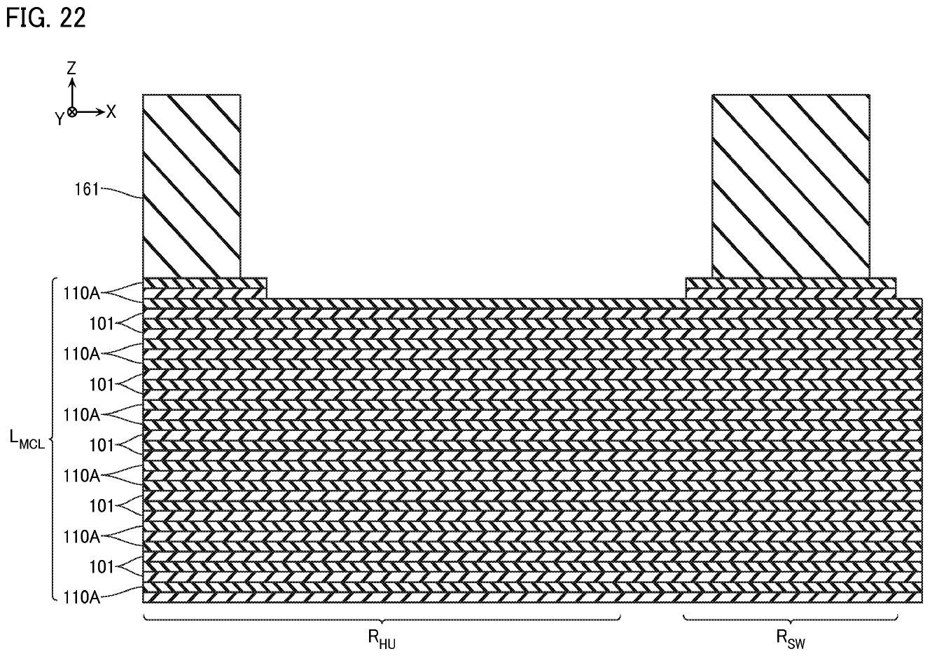

Next, as illustrated in FIG. 22, parts of the resist 161 is removed. In the illustrated example, in the hook-up region R_{HU}, a region corresponding to the terrace portion T of the fourth conductive layer 110 counting from the upper side in the memory cell layer L_{MCL} is exposed by this process.

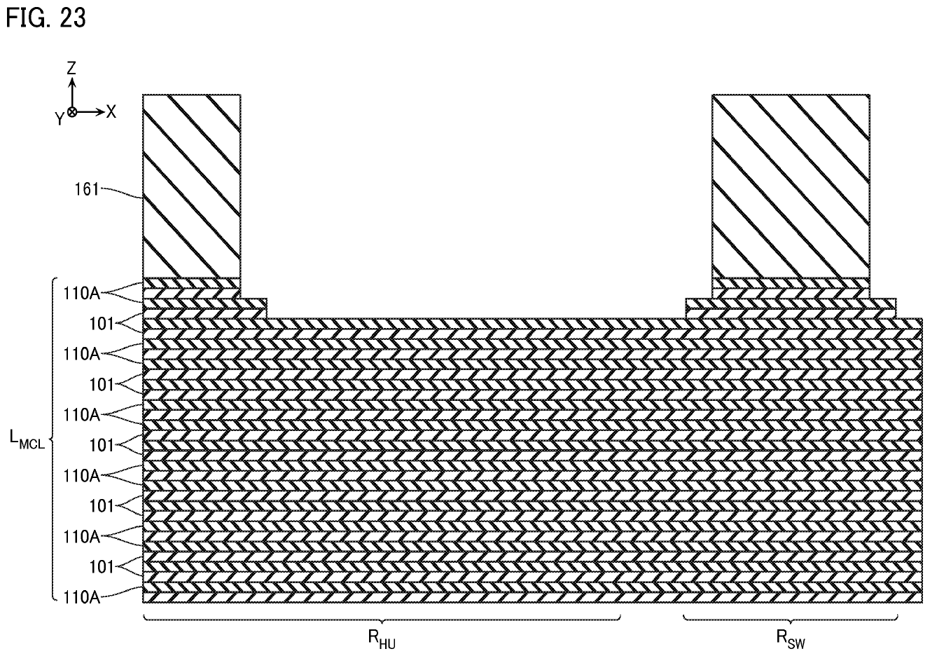

Next, as illustrated in FIG. 23, the removal of the sacrifice layer 110A and the removal of the interlayer insulating layer 101 are performed once for each. This process is performed by, for example, a method, such as wet etching or dry etching.

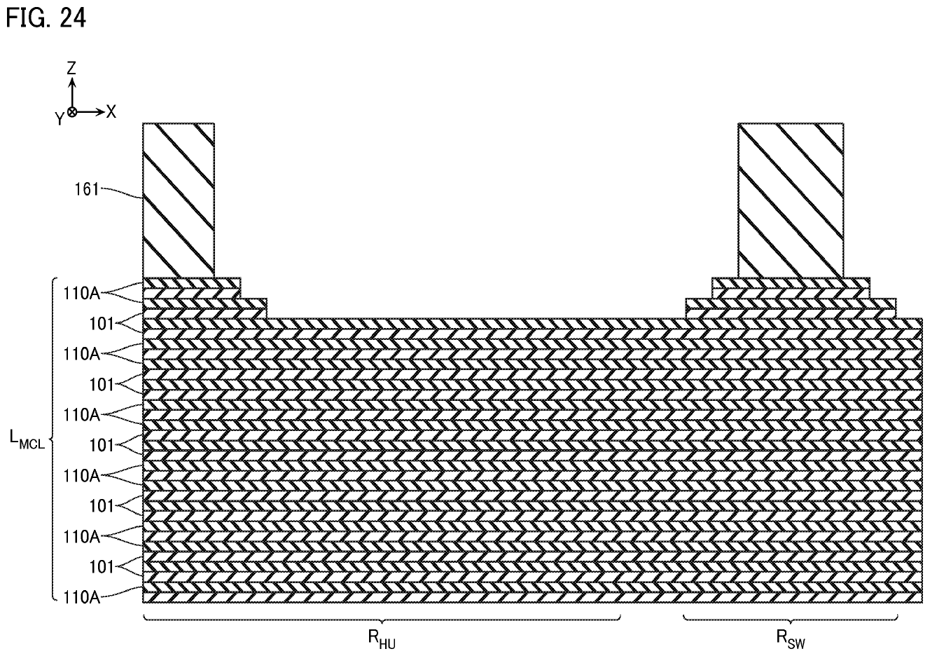

Next, as illustrated in FIG. 24, parts of the resist 161 is removed. In the illustrated example, in the hook-up region R_{HU}, a region corresponding to the terrace portion T of the third conductive layer 110 counting from the upper side in the memory cell layer L_{MCL} is exposed by this process.

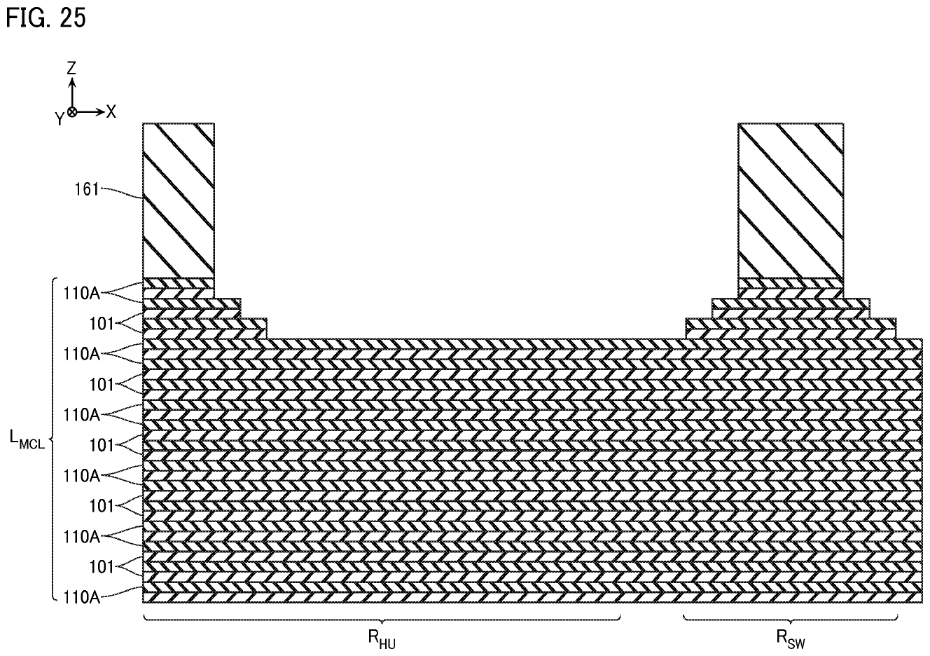

Next, as illustrated in FIG. 25, the removal of the sacrifice layer 110A and the removal of the interlayer insulating layer 101 are performed once for each. This process is performed by, for example, a method, such as wet etching or dry etching.

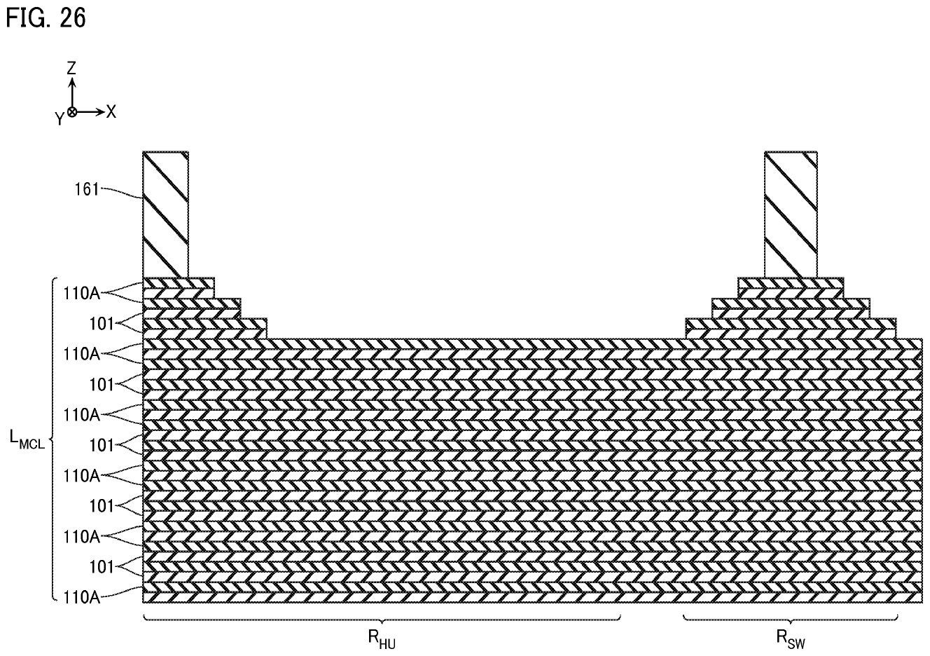

Next, as illustrated in FIG. 26, parts of the resist 161 is removed. In the illustrated example, in the hook-up region R_{HU}, a region corresponding to the terrace portion T of the second conductive layer 110 counting from the upper side in the memory cell layer L_{MCL} is exposed by this process.

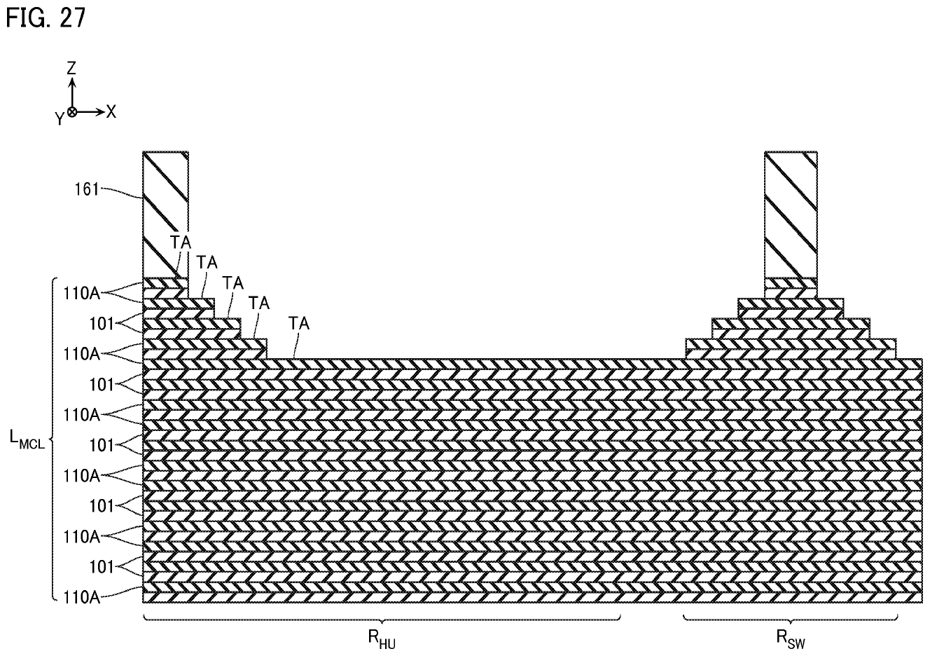

Next, as illustrated in FIG. 27, the removal of the sacrifice layer 110A and the removal of the interlayer insulating layer 101 are performed once for each. This process is performed, for example, by a method, such as wet etching or dry etching. In the illustrated example, terrace portions TA of second to fifth sacrifice layers 110A counting from the upper side are formed by the process. The terrace portion TA is a part of an upper surface of the sacrifice layer 110A that is disposed at a position that does not overlap with other sacrifice layers 110A when viewed from above. These terrace portions TA correspond to the terrace portions T of the second to fifth conductive layers 110 counting from the upper side in the memory cell layer L_{MCL}.

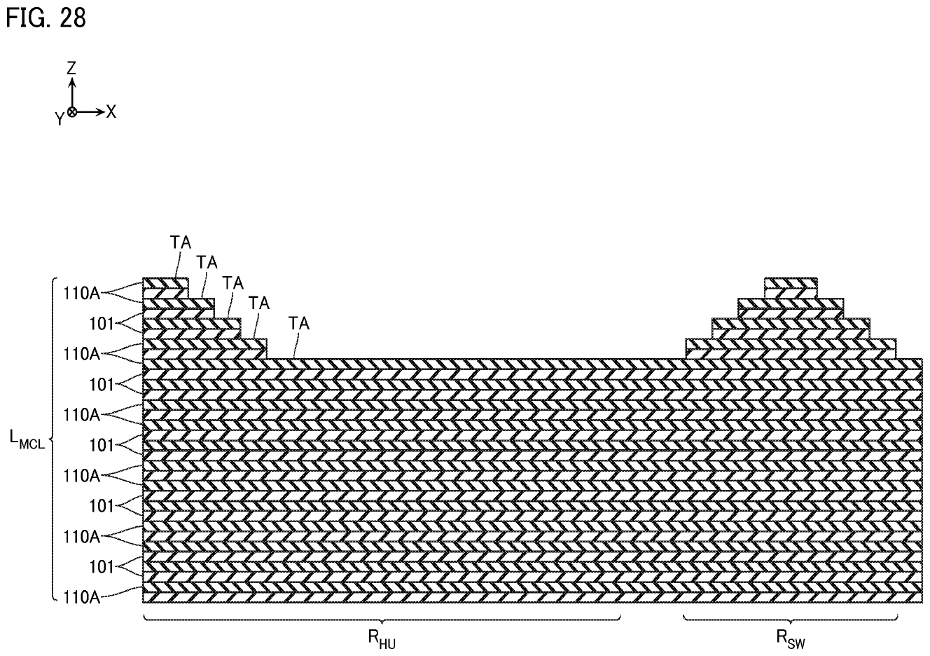

Next, as illustrated in FIG. 28, the resist 161 is removed.

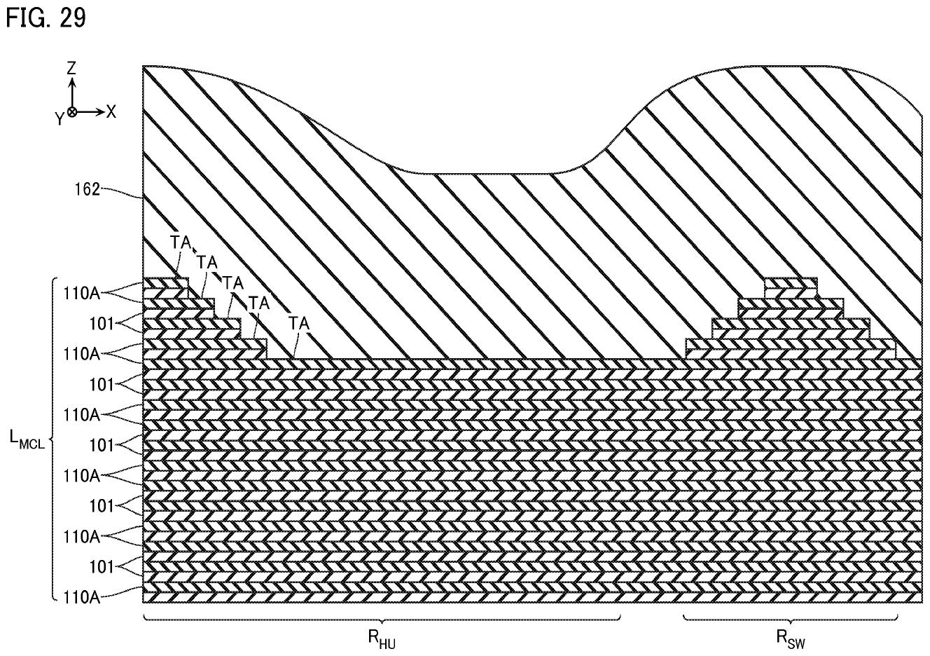

Next, as illustrated in FIG. 29, a resist 162 is formed.

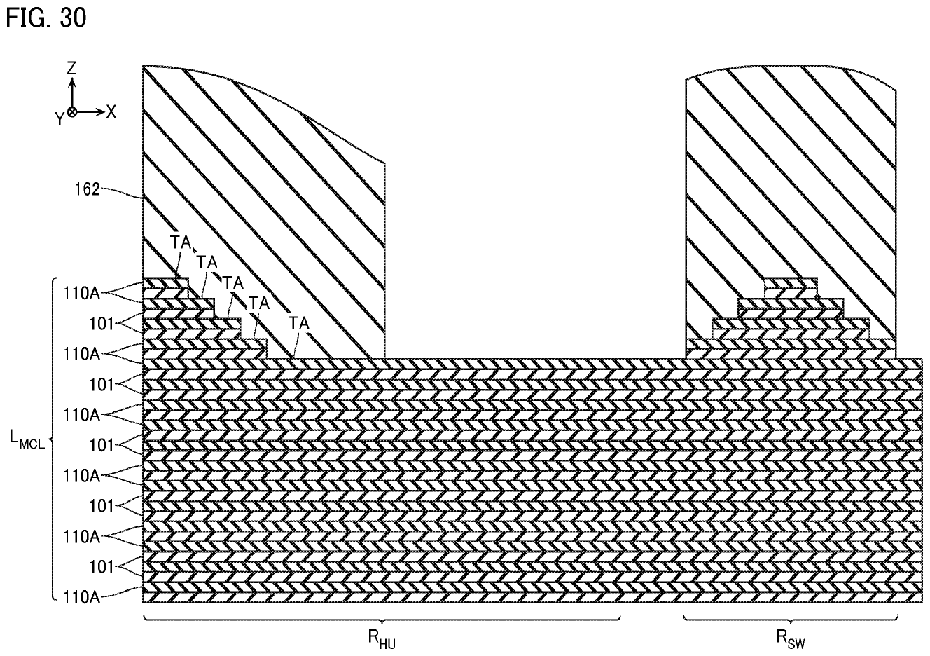

Next, as illustrated in FIG. 30, parts of the resist 162 is removed. The resist 162 is basically removed similarly to the resist 161. However, in addition to the region covered by the resist 161 in the process described with reference to FIG. 20, the resist 162 covers a region corresponding to terrace portions T of a part of the conductive layers 110 (in the illustrated example, fifth to eighth conductive layers 110 counting from the upper side in the memory cell layer L_{MCL}).

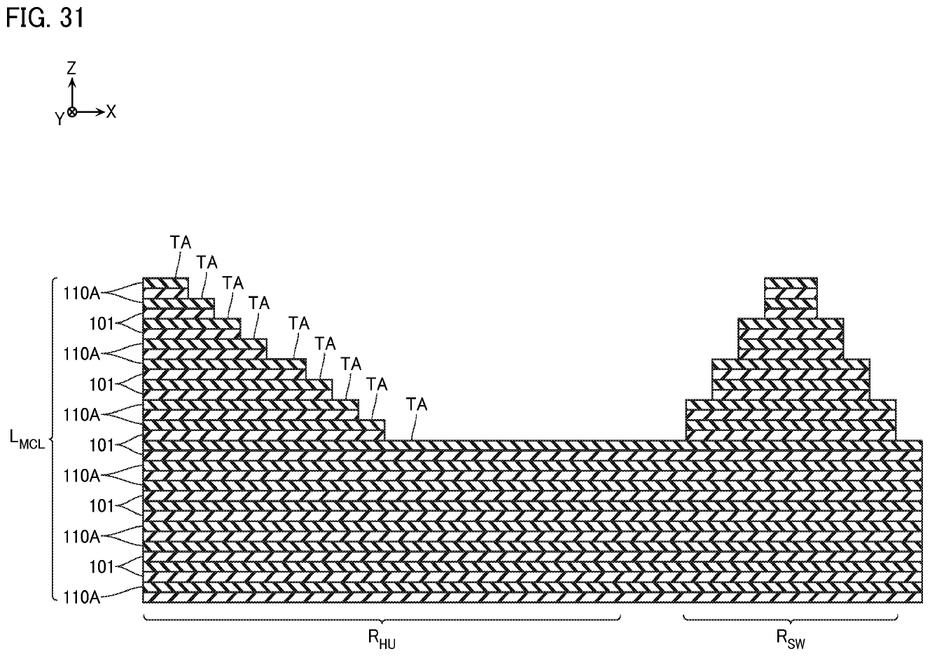

Next, the processes similar to the processes described with reference to FIG. 21 to FIG. 28 are performed. In the example of FIG. 31, terrace portions TA of sixth to ninth sacrifice layers 110A counting from the upper side are formed by the processes. These terrace portions TA correspond to terrace portions T of sixth to ninth conductive layers 110 counting from the upper side in the memory cell layer L_{MCL}.

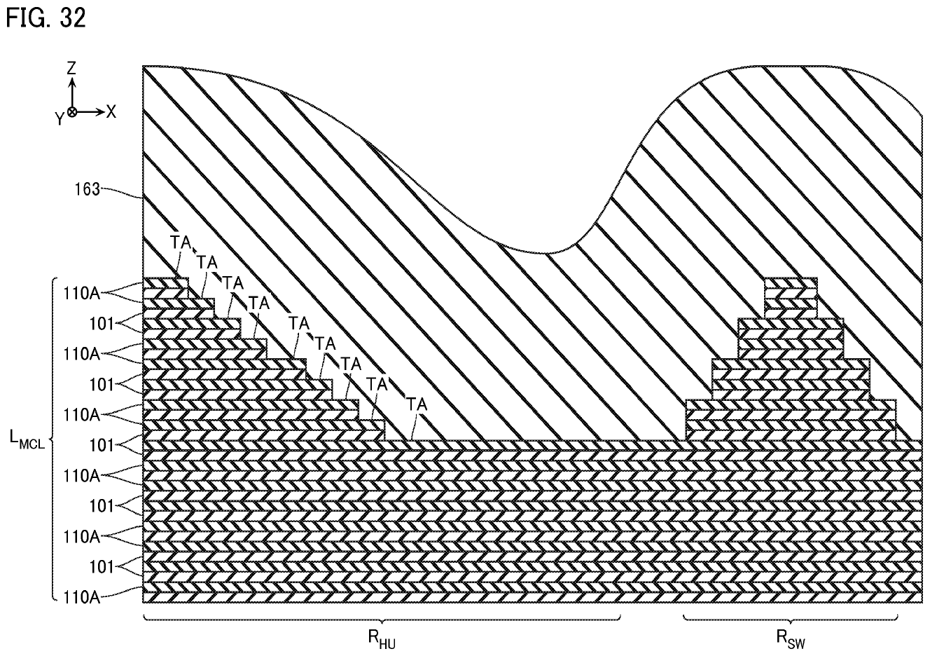

Next, as illustrated in FIG. 32, a resist 163 is formed.

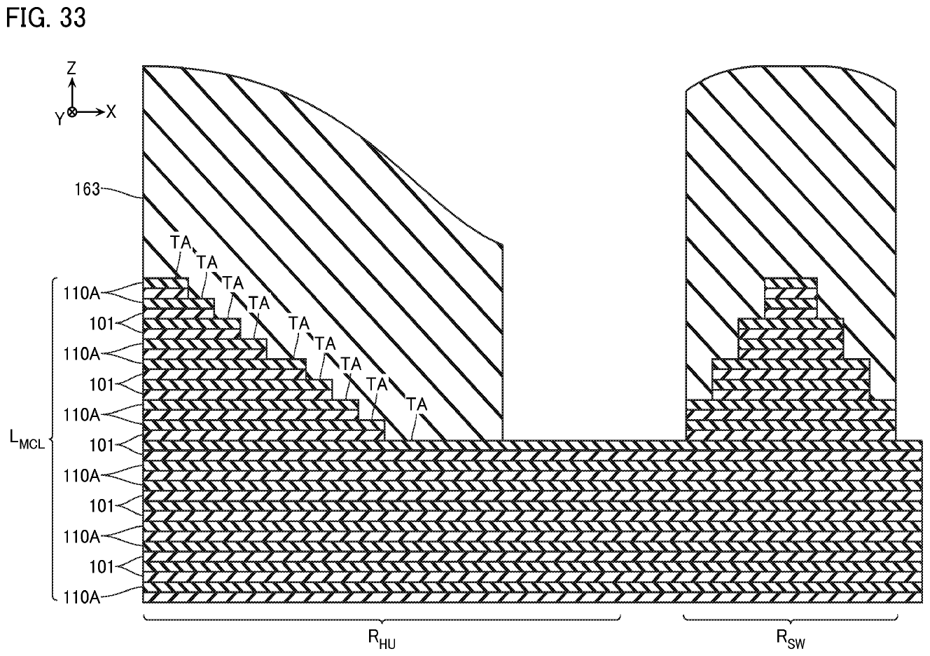

Next, as illustrated in FIG. 33, parts of the resist 163 is removed. The resist 163 is basically removed similarly to the resist 162. However, in addition to the region covered by the resist 162 in the process described with reference to FIG. 30, the resist 163 covers a region corresponding to terrace portions T of a part of the conductive layers 110 (in the illustrated example, ninth to twelfth conductive layers 110 counting from the upper side in the memory cell layer L_{MCL}).

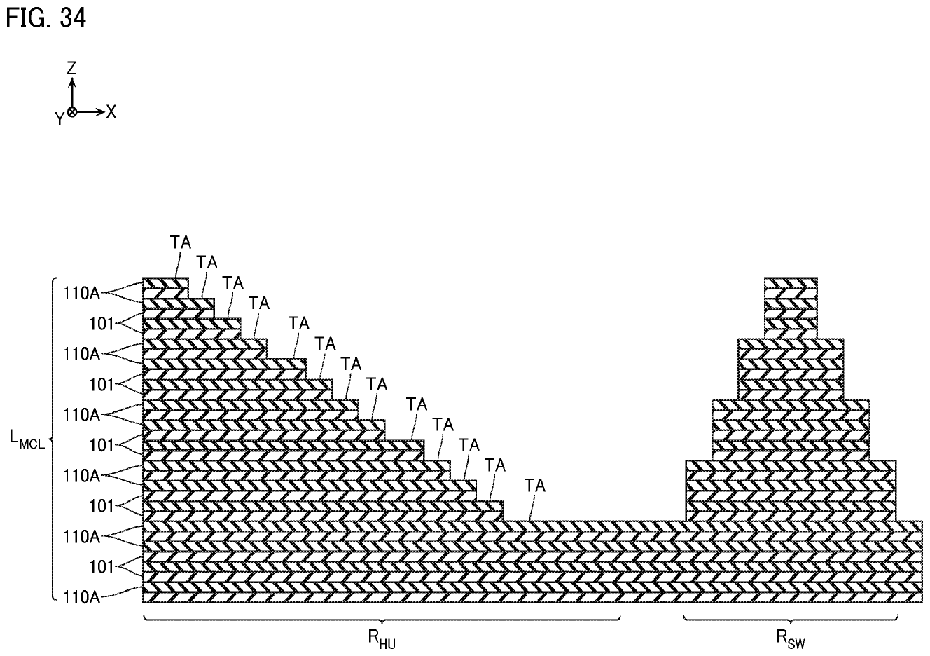

Next, the processes similar to the processes described with reference to FIG. 21 to FIG. 28 are performed. In the example of FIG. 34, terrace portions TA of tenth to thirteenth sacrifice layers 110A counting from the upper side are formed by the processes. These terrace portions TA correspond to tenth to thirteenth terrace portions T counting from the upper side in the memory cell layer L_{MCL}.

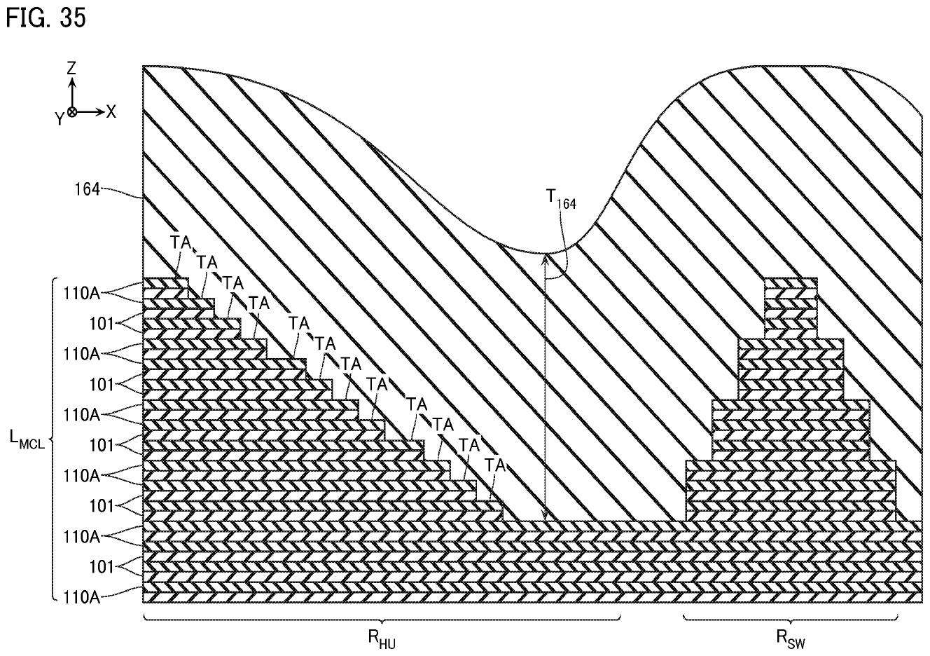

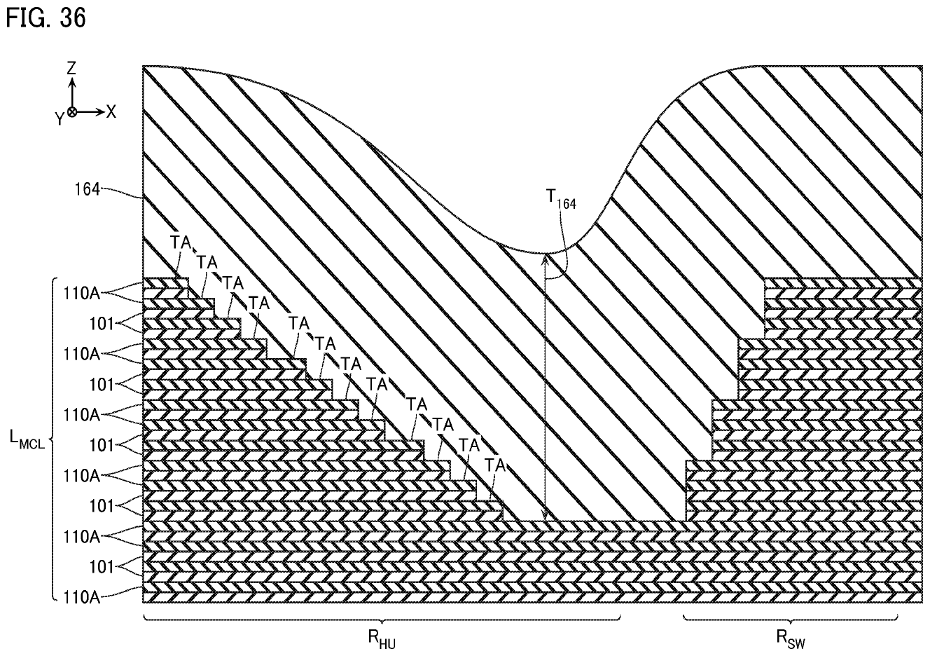

Next, as illustrated in FIG. 35 and FIG. 36, a resist 164 is formed. Note that FIG. 35 illustrates an enlarged cross-sectional surface corresponding to a part of FIG. 4, and FIG. 36 illustrates an enlarged cross-sectional surface corresponding to a part of FIG. 3.

Here, in the process corresponding to FIG. 19, the resist 161 is formed on the surface of a flat structure. Therefore, a variation in film thickness of the resist 161 is relatively small. On the other hand, as the formation of the structures corresponding to the terrace portions T advances, a recessed portion is formed between the hook-up region R_{HU} and the stacked body region R_{SW} by the plurality of interlayer insulating layers 101 and the plurality of sacrifice layers 110A, and a depth of the recessed portion gradually increases. In association with this, the film thickness of a resist formed in the recessed portion gradually increases. For example, in the process corresponding to FIG. 35, a film thickness T₁₆₄ in the Z-direction of the resist 164 formed between the stacked body region R_{SW} and the hook-up region R_{HU} is greater than a film thickness T₁₆₁ in the Z-direction of the resist 161 formed at this position in the process corresponding to FIG. 19.

As described above, in the embodiment, the stacked body region R_{SW} extending in the Y-direction is formed between the non-stacked body region R_{SN} and the hook-up region R_{HU} and between the stacked body regions R_{SS} and the hook-up region R_{HU}. Therefore, as illustrated in FIG. 35 and FIG. 36, the film thickness T₁₆₄ in the Z-direction of the resist 164 formed between the stacked body region R_{SW} and the hook-up region R_{HU} at the proximity of the non-stacked body region R_{SN} is similar in size to that at the proximity of the stacked body region R_{SS}.

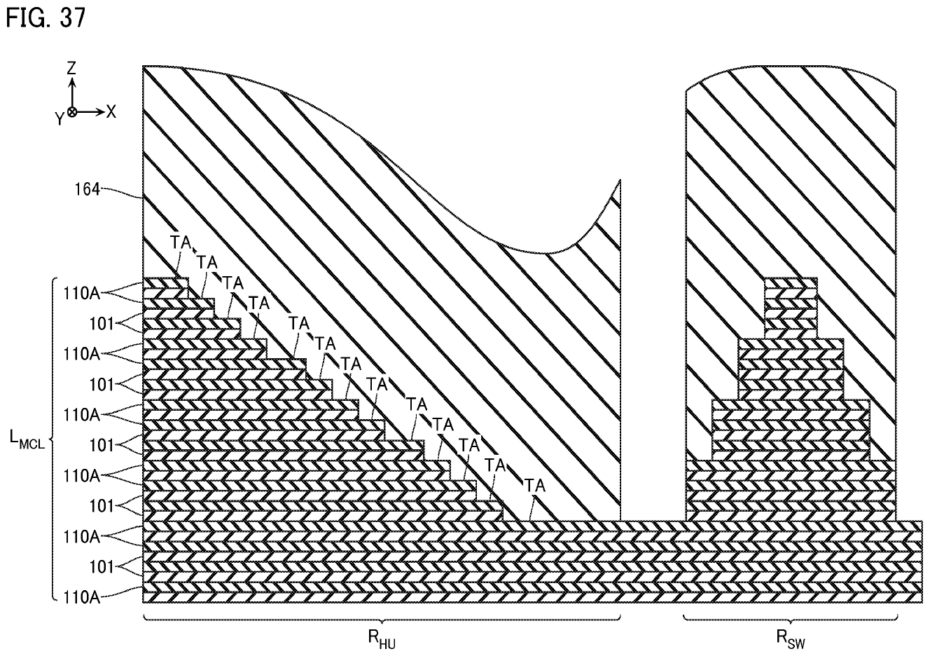

Next, as illustrated in FIG. 37, parts of the resist 164 is removed. The resist 164 is basically removed similarly to the resist 163. However, in addition to the region covered by the resist 163 in the process described with reference to FIG. 33, the resist 164 covers a region corresponding to terrace portions T of a part of the conductive layers 110 (in the illustrated example, thirteenth to sixteenth conductive layers 110 counting from the upper side in the memory cell layer L_{MCL}).

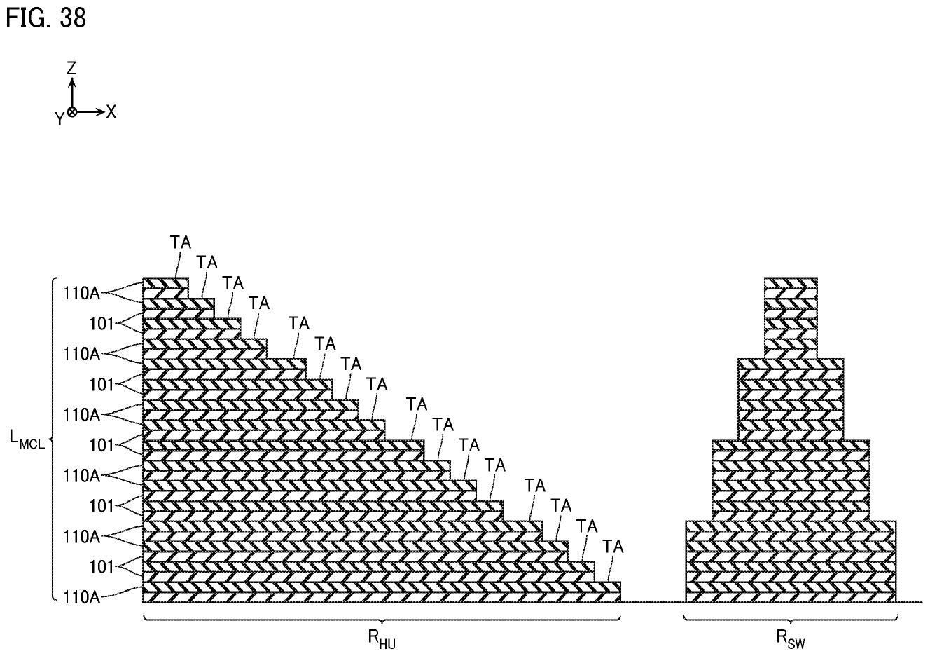

Next, the processes similar to the processes described with reference to FIG. 21 to FIG. 28 are performed. In the example of FIG. 38, terrace portions TA of fourteenth to sixteenth sacrifice layers 110A counting from the upper side are formed by the processes. These terrace portions TA correspond to terrace portions T of fourteenth to sixteenth conductive layers 110 counting from the upper side in the memory cell layer L_{MCL}.

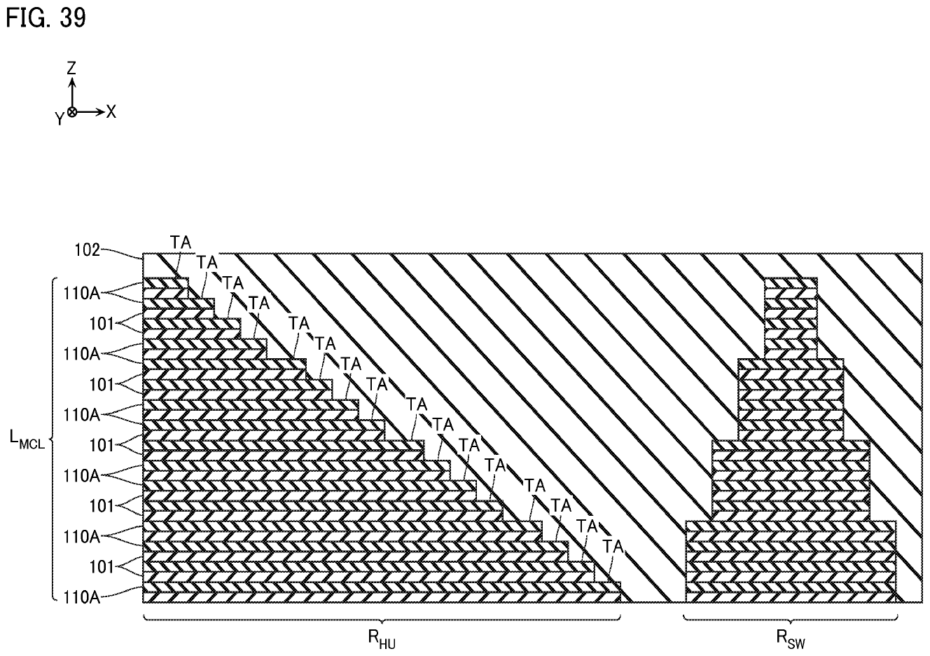

Next, as illustrated in FIG. 39, the insulating layer 102 is formed in the memory cell region R_{MC} and the hook-up region R_{HU}. This process is performed by, for example, a method, such as CVD.

Next, as illustrated in FIG. 40, a plurality of memory holes LMH are formed at positions corresponding to the plurality of semiconductor columns 120. These plurality of memory holes LMH extend in the Z-direction, pass through the plurality of interlayer insulating layers 101 and the plurality of sacrifice layers 110A, and expose a surface of the conductive layer 100. This process is performed by, for example, a method, such as Reactive Ion Etching (RIE).

Note that, as illustrated in FIG. 41, in this process, the recessed portion 145 is formed in the marked region R_{MK} in parallel with the memory holes LMH. The recessed portion 145 has an inner diameter greater than an inner diameter of the memory hole LMH. Further, the recessed portion 145 passes through only a part of the plurality of interlayer insulating layers 101 and a part of the layers 150 formed so as to correspond to the plurality of sacrifice layers 110A. Therefore, the recessed portion 145 has a bottom surface to which the interlayer insulating layer 101 or the layer 150 is exposed.

Next, as illustrated in FIG. 42, sacrifice columns 120A are formed inside the memory holes LMH. The sacrifice column 120A contains, for example, silicon (Si) or the like. This process is performed by, for example, a method, such as CVD.

Next, as illustrated in FIG. 43, the plurality of interlayer insulating layers 101 and the plurality of sacrifice layers 110A are formed in alternation in the memory cell layer L_{MCU}. This process is performed by, for example, a method, such as CVD.

As illustrated in FIG. 44, in this process, in the marked region R_{MK}, the plurality of interlayer insulating layers 101 and the layers 150 corresponding to the plurality of sacrifice layers 110A are formed along the recessed portion 145. Further, as illustrated in FIG. 44 and FIG. 45, the recessed portion 146 is formed on an upper surface of the uppermost layer 150.

Next, the processes similar to the processes described with reference to FIG. 19 to FIG. 38 are performed. However, in the processes, instead of the terrace portions TA in the memory cell layer L_{MCL}, the terrace portions TA in the memory cell layer L_{MCU} are formed as illustrated in FIG. 46.

Next, as illustrated in FIG. 47, the insulating layer 103 is formed in the memory cell region R_{MC} and the hook-up region R_{HU}. This process is performed by, for example, a method, such as CVD.

Next, as illustrated in FIG. 48, a plurality of memory holes UMH are formed at positions corresponding to the plurality of semiconductor columns 120. These plurality of memory holes UMH extend in the Z-direction, pass through the plurality of interlayer insulating layers 101 and the plurality of sacrifice layers 110A in the memory cell layer L_{MCU}, and expose surfaces of the sacrifice columns 120A. This process is performed by, for example, a method, such as RIE.

In this process, using the recessed portion 146 in the marked region R_{MK} described with reference to FIG. 45 as a reference, the memory holes UMH are positioned.

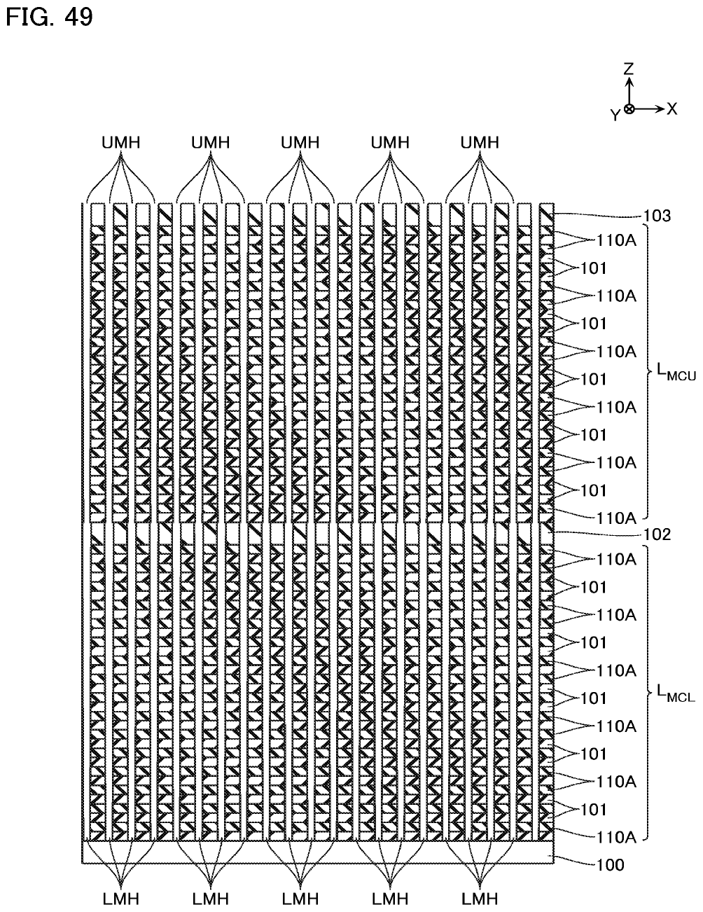

Next, as illustrated in FIG. 49, the sacrifice columns 120A are removed. This process is performed by, for example, a method, such as wet etching.

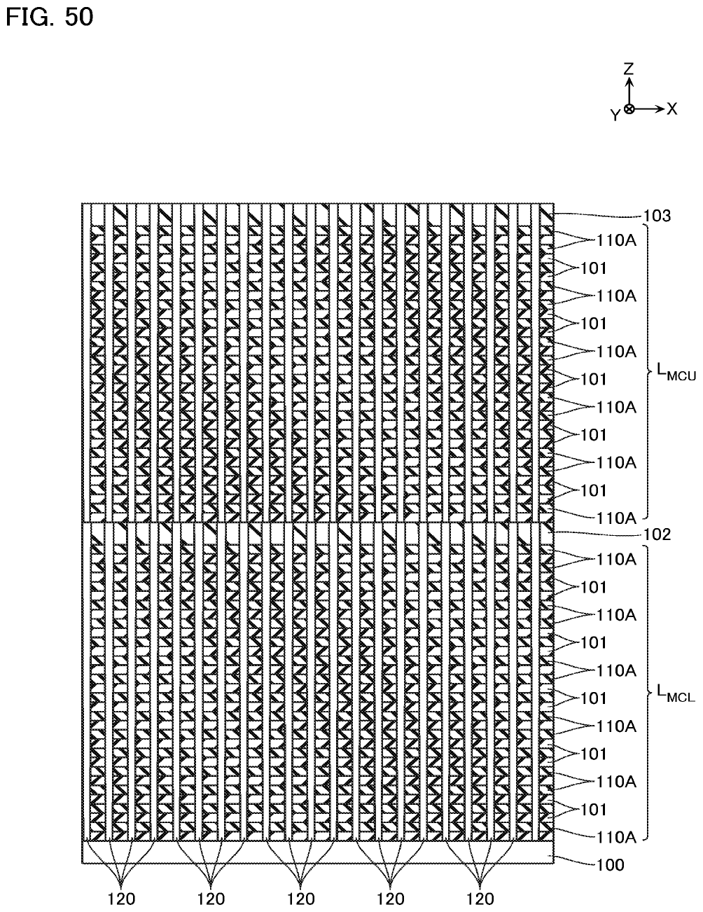

Next, as illustrated in FIG. 50, the plurality of semiconductor columns 120 are formed inside the memory holes LMH, UMH. Although the illustration is omitted, inside the memory holes LMH, UMH, the gate insulating films 130 (FIG. 6) are formed before the plurality of semiconductor column 120, and the insulating columns 125 (FIG. 6) are formed after the plurality of semiconductor columns 120. This process is performed by, for example, a method, such as CVD.

Next, as illustrated in FIG. 51, the trench STA is formed at a position corresponding to the inter-finger structure ST. The trench STA extends in the Z-direction and the X-direction, separates the plurality of interlayer insulating layers 101 and the plurality of sacrifice layers 110A in the Y-direction, and exposes the conductive layer 100. This process is performed by, for example, a method, such as RIE.

Next, as illustrated in FIG. 52, the sacrifice layers 110A are removed via the trench STA to form a plurality of voids 110B between each two of the plurality of interlayer insulating layers 101. As a result, a hollow structure including the plurality of interlayer insulating layers 101 stacked in the Z-direction and a structure inside the memory holes LMH, UMH supporting these interlayer insulating layers 101 (the semiconductor column 120, the gate insulating film 130, and the insulating column 125) is formed. This process is performed by, for example, a method, such as wet etching.

Next, as illustrated in FIG. 53, the conductive layers 110 are formed in the plurality of voids 110B. This process is performed by, for example, a method, such as CVD.

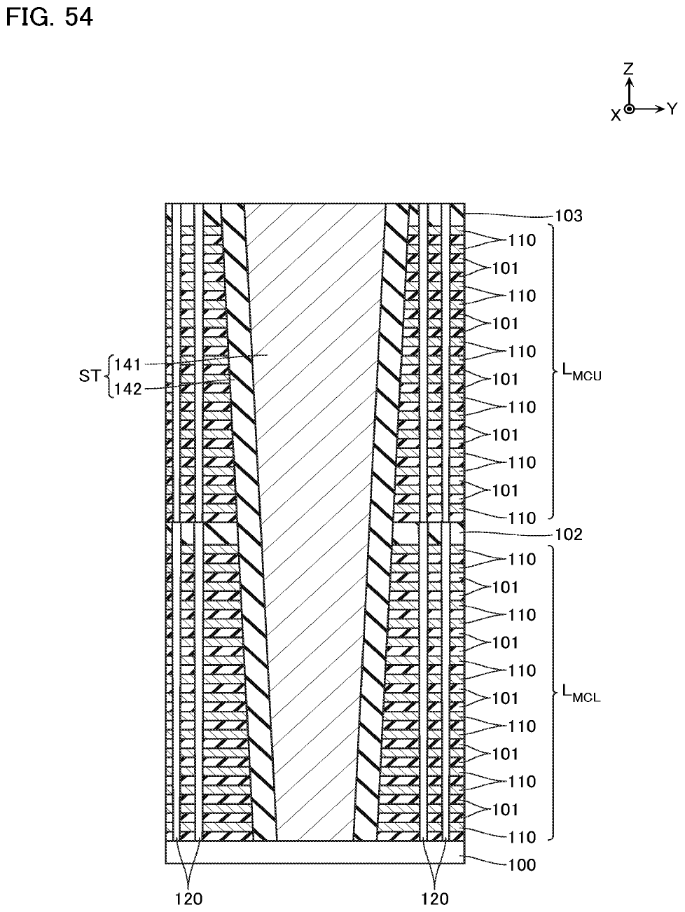

Next, as illustrated in FIG. 54, the inter-finger structure ST is formed in the trench STA. This process is performed by, for example, methods, such as CVD and RIE.

Subsequently, the via-contact electrodes Ch, Vy and the bit lines BL described with reference to FIG. 5 and the via-contact electrodes CC and the like described with reference to FIG. 7 are formed, thereby forming the memory wafer MW described with reference to FIG. 11 and the like. Further, as described above, the memory die MD described with reference to FIG. 1 and the like is formed by dicing the memory wafer MW.

### Comparative Example

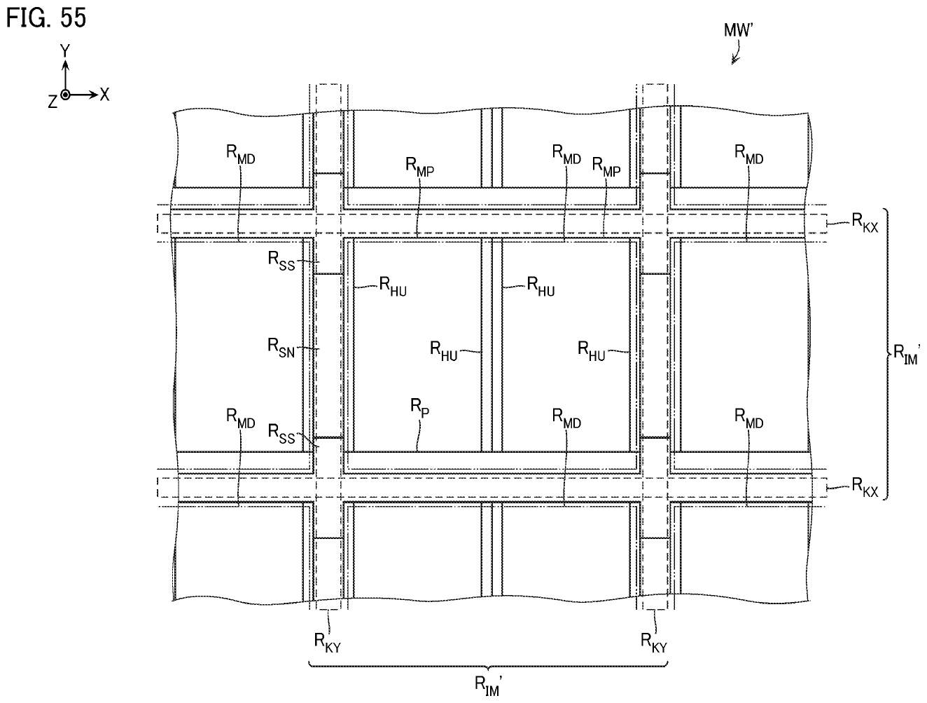

Next, a configuration of a memory wafer MW′ according to a comparative example is described. FIG. 55 is a schematic plan view illustrating the configuration of the memory wafer MW′. An inter-memory region R_{IM}′ in the memory wafer MW′ does not include the stacked body region R_{SW}.

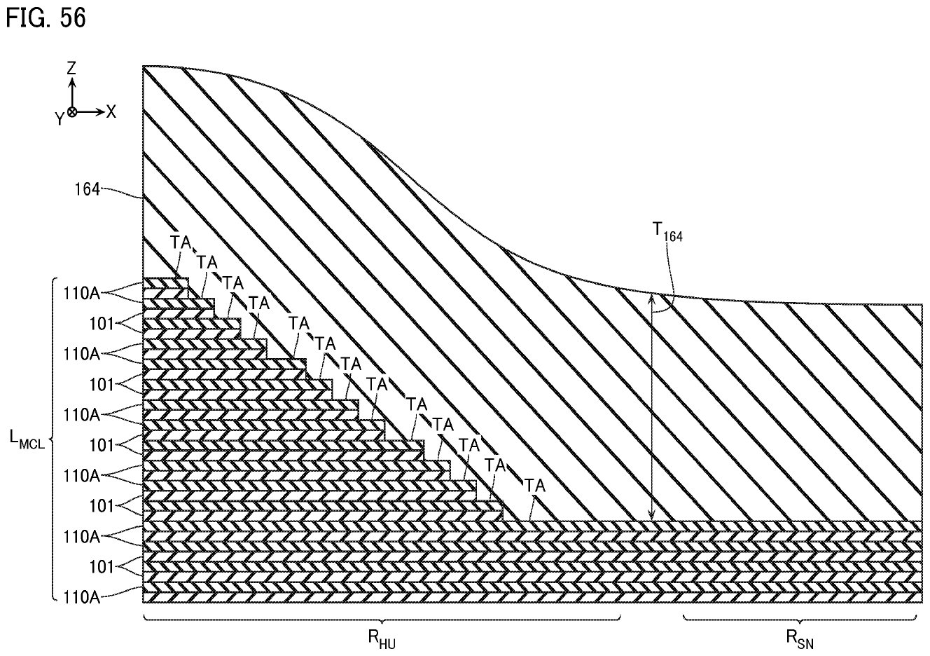

A method of manufacturing the memory wafer MW′ according to the comparative example is described below. FIG. 56 is a schematic cross-sectional view for describing the manufacturing method.

To manufacture the memory wafer MW′ according to the comparative example, in the processes corresponding to FIG. 19 to FIG. 38, the terrace portions TA in the memory cell layer L_{MCL} are formed.

As described with reference to FIG. 35 and the like, as the formation of the terrace portions TA advances, a recessed portion is formed between the hook-up region R_{HU} and the stacked body region R_{SS} by the plurality of interlayer insulating layers 101 and the plurality of sacrifice layers 110A, and a depth of the recessed portion gradually increases (see FIG. 36). In association with this, the film thickness of a resist formed in the recessed portion gradually increases by the formed resist accumulating in the recessed portion.

Here, the memory wafer MW′ according to the comparative example does not include the stacked body region R_{SW}. Therefore, in manufacturing the memory wafer MW′ according to the comparative example, as illustrated in FIG. 56, the film thickness T₁₆₄ in the Z-direction of the resist 164 is relatively small at the proximity of the non-stacked body region R_{SN}. The film thickness T₁₆₄ in the Z-direction of the resist 164 is relatively large at the proximity of the stacked body region R_{SS} (see FIG. 36). That is, a variation in the film thickness T₁₆₄ in the Z-direction of the resist 164 formed between the inter-memory region R_{IM}′ and the hook-up region R_{HU} occurs between at the proximity of the non-stacked body region R_{SN} and at the proximity of the stacked body region R_{SS}.

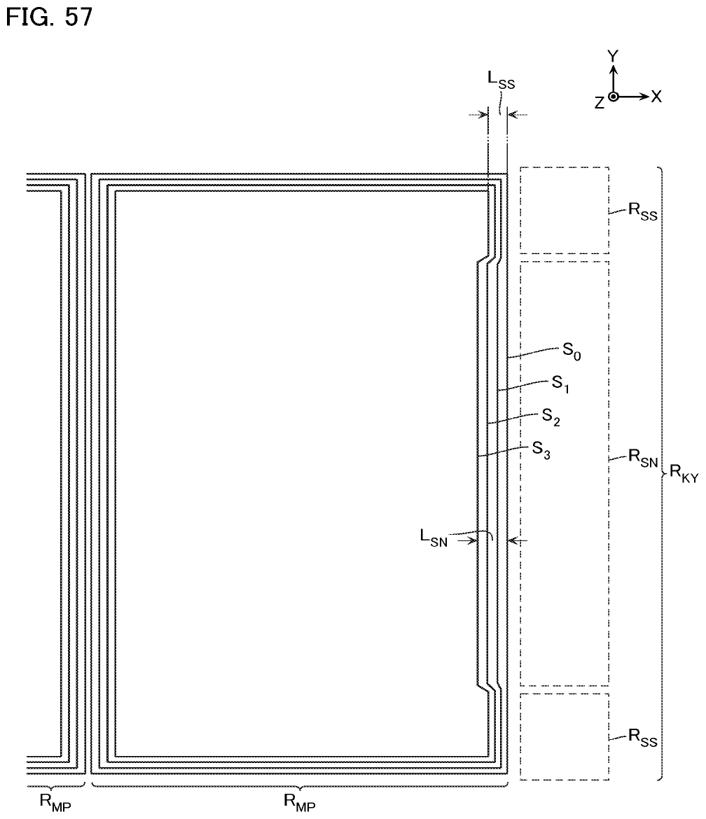

FIG. 57 is a schematic plan view for describing a part of the manufacturing method of the memory wafer MW′ according to the comparative example. FIG. 57 indicates a planar shape of the resist 164 after performing the process corresponding to FIG. 37 as S₀. Further, in the processes corresponding to FIG. 22, FIG. 24, and FIG. 26 between the process corresponding to FIG. 37 and the process corresponding to FIG. 38, the resist 164 is gradually removed over three times. FIG. 57 indicates planar shapes of the resist 164 at these times as S₁ to S₃.

When the variation in the film thickness T₁₆₄ of the resist 164 as described above occurs, as illustrated in FIG. 57, a difference occurs between a removal amount L_{SN} of the resist 164 at the proximity of the non-stacked body region R_{SN} and a removal amount L_{SS} of the resist 164 at the proximity of the stacked body region R_{SS}. When such a difference increases, the via-contact electrodes CC (FIG. 7) cannot possibly be connected preferably to the conductive layers 110.

### Effect of First Embodiment

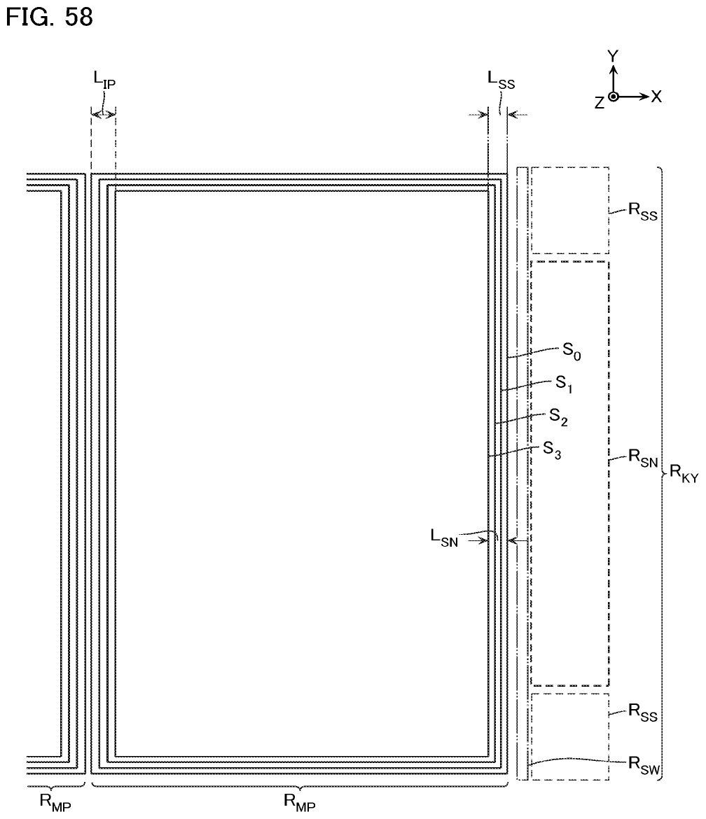

FIG. 58 is a schematic plan view for describing a part of the manufacturing method of the memory wafer MW according to the first embodiment. FIG. 58 indicates the planar shape of the resist 164 after performing the process described with reference to FIG. 37 as S₀. Further, in the processes corresponding to FIG. 22, FIG. 24, and FIG. 26 between the process described with reference to FIG. 37 and the process described with reference to FIG. 38, the resist 164 is gradually removed over three times. FIG. 58 indicates the planar shapes of the resist 164 at these times as S₁ to S₃.

As described above, in the first embodiment, as illustrated in FIG. 35 and FIG. 36, the film thickness T₁₆₄ in the Z-direction of the resist 164 formed between the stacked body region R_{SW} and the hook-up region R_{HU} at the proximity of the non-stacked body region R_{SN} is similar in size to that at the proximity of the stacked body region R_{SS}. Accordingly, the difference between the removal amount L_{SN} of the resist 164 at the proximity of the non-stacked body region R_{SN} and the removal amount L_{SS} of the resist 164 at the proximity of the stacked body region R_{SS} as described with reference to FIG. 57 can preferably be suppressed.

### Second Embodiment

### Memory Die MD2

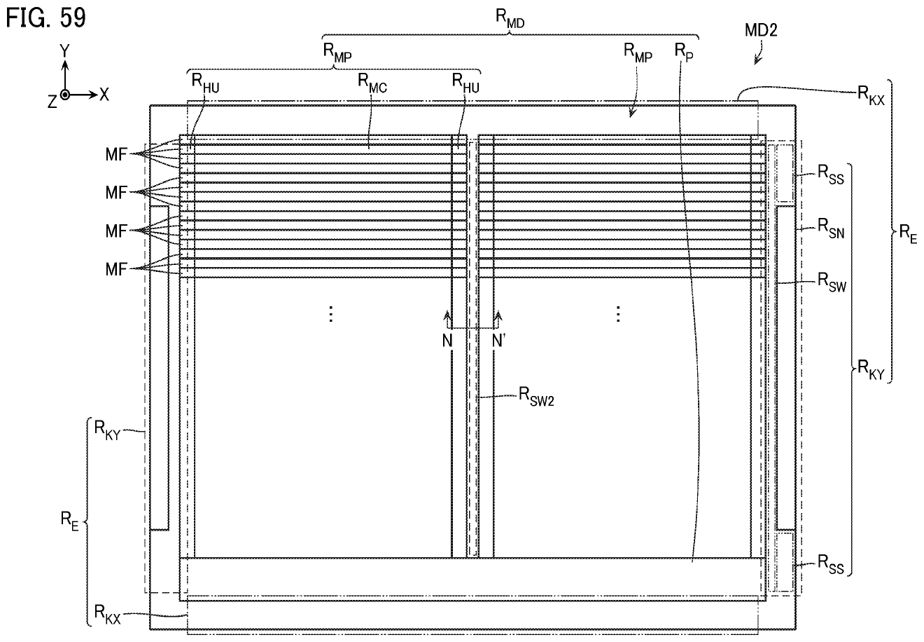

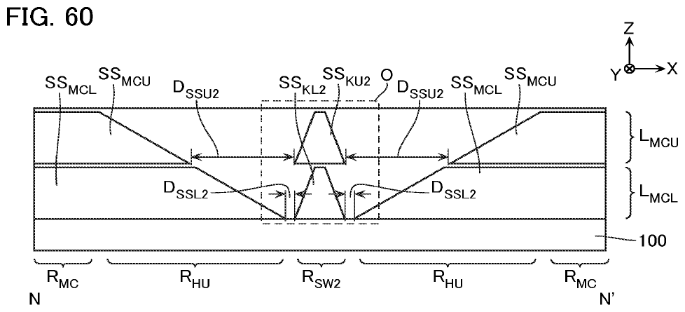

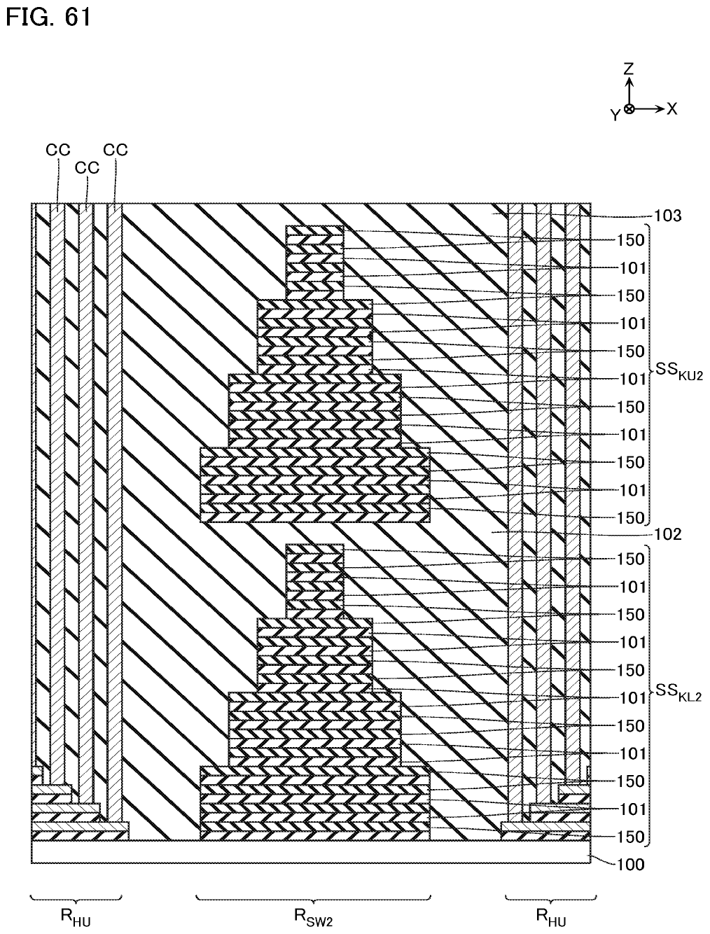

Next, with reference to FIG. 59 to FIG. 61, a configuration of a memory die MD2 according to a second embodiment is described. FIG. 59 is a schematic plan view illustrating the configuration of the memory die MD2. FIG. 60 and FIG. 61 are schematic cross-sectional views illustrating a configuration of a part of the memory die MD2. FIG. 60 illustrates a schematic cross-sectional surface of the structure illustrated in FIG. 59 taken along the line N-N′ and viewed along a direction of arrows. FIG. 61 illustrates an enlarged part indicated by O in FIG. 60.

The memory die MD2 according to the second embodiment is basically configured similarly to the memory die MD according to the first embodiment. However, as illustrated in FIG. 59, the memory die MD2 includes a stacked body region R_{SW2} disposed between the two memory plane regions R_{MP} arranged in the X-direction. The stacked body region R_{SW2} extends in the Y-direction along from one end to the other end in the Y-direction of the memory plane region R_{MP}. That is, the stacked body region R_{SW2} extends in the Y-direction along from one end to the other end in the Y-direction of the plurality of memory finger structures MF arranged in the Y-direction. Further, as illustrated in FIG. 60 and FIG. 61, the stacked body region R_{SW2} includes a stacked body SS_{KL2} and a stacked body SS_{KU2}. The stacked bodies SS_{KL2}, SS_{KU2} are configured similarly to the stacked bodies SS_{KL}, SS_{KU}, respectively.

Note that the stacked bodies SS_{KL2}, SS_{KU2} have lengths in the X-direction smaller than lengths in the X-direction of the stacked bodies SS_{MCL}, SS_{MCU}. The lengths in the X-direction of the stacked bodies SS_{KL2}, SS_{KU2} may be, for example, lengths in the X-direction of the lowermost layers 150 of those included in the stacked bodies SS_{KL2}, SS_{KU2} (the layers 150 closest to the conductive layer 100). The lengths in the X-direction of the stacked bodies SS_{MCL}, SS_{MCU} may be, for example, lengths in the X-direction of the lowermost conductive layers 110 of those included in the stacked bodies SS_{MCL}, SS_{MCU} (the conductive layers 110 closest to the conductive layer 100).

FIG. 60 exemplifies two stacked bodies SS_{MCL} arranged in the X-direction in the memory cell layer L_{MCL} and one stacked body SS_{KL2} disposed between the two stacked bodies SS_{MCL}. Here, a distance D_{SSL2} in the X-direction between one stacked body SS_{MCL} and the stacked body SS_{KL2} approximately matches a distance D_{SSL2} in the X-direction between the other stacked body SS_{MCL} and the stacked body SS_{KL2}. Further, these distances D_{SSL2} approximately match the distance D_{SSL} (FIG. 4) in the X-direction between the stacked body SS_{MCL} and the stacked body SS_{KL}. These distances D_{SSL2} are approximately constant from one end to the other end in the Y-direction of the memory plane region R_{MP} (FIG. 59). That is, the distance D_{SSL2} is approximately constant from one end to the other end in the Y-direction of the plurality of memory finger structures MF arranged in the Y-direction.

Note that the distance D_{SSL2} in the X-direction between the stacked body SS_{MCL} and the stacked body SS_{KL2} may be, for example, a distance in the X-direction between the lowermost conductive layer 110 of those included in the stacked body SS_{MCL} (the conductive layer 110 closest to the conductive layer 100) and the lowermost layer 150 of those included in the stacked body SS_{KL2} (the layer 150 closest to the conductive layer 100).

Similarly, FIG. 60 exemplifies two stacked bodies SS_{MCU} arranged in the X-direction in the memory cell layer L_{MCU} and one stacked body SS_{KU2} disposed between the two stacked bodies SS_{MCU}. Here, a distance D_{SSU2} in the X-direction between one stacked body SS_{MCU} and the stacked body SS_{KU2} approximately matches a distance D_{SSU2} in the X-direction between the other stacked body SS_{MCU} and the stacked body SS_{KU2}. Further, these distances D_{SSU2} approximately match the distance D_{SSU} (FIG. 4) in the X-direction between the stacked body SS_{MCU} and the stacked body SS_{KU}. Therefore, the distance D_{SSU2} is greater than the distance D_{SSL2}. Further, these distances D_{SSU2} are approximately constant from one end to the other end in the Y-direction of the memory plane region R_{MP} (FIG. 59). That is, the distance D_{SSU2} is approximately constant from one end to the other end in the Y-direction of the plurality of memory finger structures MF arranged in the Y-direction.

Note that the distance D_{SSU2} in the X-direction between the stacked body SS_{MCU} and the stacked body SS_{KU2} may be, for example, a distance in the X-direction between the lowermost conductive layer 110 of those included in the stacked body SS_{MCU} (the conductive layer 110 closest to the conductive layer 100) and the lowermost layer 150 of those included in the stacked body SS_{KU2} (the layer 150 closest to the conductive layer 100).

### Effect of Second Embodiment

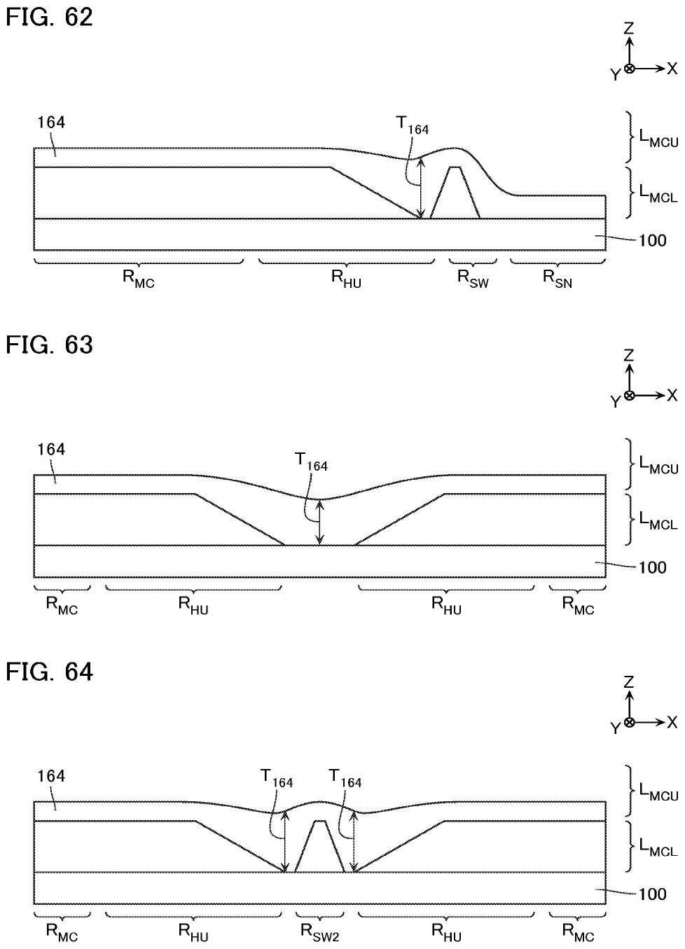

FIG. 62 and FIG. 63 are schematic cross-sectional views for describing a manufacturing process of the memory die MD according to the first embodiment. FIG. 62 and FIG. 63 illustrate a state after performing the process described with reference to FIG. 35.

As described with reference to FIG. 1, in the first embodiment, the hook-up regions R_{HU} are disposed at both end portions in the X-direction of the memory finger structures MF. In the first embodiment, the stacked body region R_{SW} is disposed at the proximity of the closer of these two hook-up regions R_{HU} to the kerf region R_{KY} (for example, the hook-up region R_{HU} on the X-direction positive side in the memory plane region R_{MP} disposed on the X-direction positive side). Accordingly, as described with reference to FIG. 58, the difference between the removal amount L_{SN} of the resist 164 at the proximity of the non-stacked body region R_{SN} and the removal amount L_{SS} of the resist 164 at the proximity of the stacked body region R_{SS} can preferably be suppressed.

Here, in the process described with reference to FIG. 35, as illustrated in FIG. 63, for example, a recessed portion is formed also between two memory plane regions R_{MP} adjacent in the X-direction. The recessed portion has a width in the X-direction greater than a width in the X-direction of the recessed portion formed between the stacked body region R_{SW} and the hook-up region R_{HU}. Therefore, in manufacturing the memory die MD according to the first embodiment, as illustrated in FIG. 62 and FIG. 63, a difference possibly occurs in the film thickness T₁₆₄ in the Z-direction of the resist 164 formed in the recessed portion between a position between the two memory plane regions R_{MP} and a position between the stacked body region R_{SW} and the hook-up region R_{HU}.

FIG. 64 is a schematic cross-sectional view for describing a manufacturing process of the memory die MD2 according to the second embodiment. FIG. 64 illustrates a state after performing the process corresponding to FIG. 35.

In the memory die MD2 according to the second embodiment, the stacked body region R_{SW2} is disposed between two memory plane regions R_{MP} arranged in the X-direction. Therefore, as illustrated in FIG. 62 and FIG. 64, the film thickness T₁₆₄ in the Z-direction of the resist 164 formed in the recessed portion between the two memory plane regions R_{MP} is similar in size to that between the stacked body region R_{SW} and the hook-up region R_{HU}.

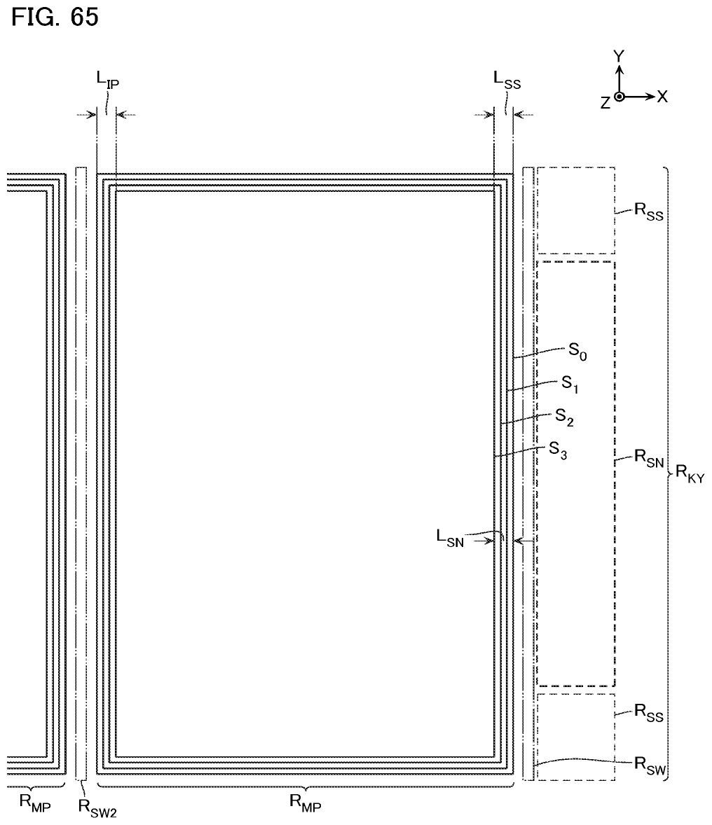

FIG. 65 is a schematic plan view for describing a part of the manufacturing method of the memory die MD2 according to the second embodiment. FIG. 65 indicates the planar shape of the resist 164 after performing the process described with reference to FIG. 37 as S₀. Further, in the processes corresponding to FIG. 22, FIG. 24, and FIG. 26 between the process described with reference to FIG. 37 and the process described with reference to FIG. 38, the resist 164 is gradually removed over three times. FIG. 65 indicates the planar shapes of the resist 164 at these times as S₁ to S₃.

As described with reference to FIG. 62 and FIG. 64, in the second embodiment, the film thickness T₁₆₄ in the Z-direction of the resist 164 formed in the recessed portion between the two memory plane regions R_{MP} is similar in size to that between the stacked body region R_{SW} and the hook-up region R_{HU}. Accordingly, as illustrated in FIG. 65, a difference between a removal amount Lip of the resist 164 between two hook-up regions R_{HU} adjacent in the X-direction and the removal amounts L_{SN}, L_{SS} of the resist 164 at the proximity of the stacked body region R_{SW} can preferably be suppressed.

### Other Embodiments

The semiconductor memory devices according to the first embodiment and the second embodiment have been described above. However, the above-mentioned semiconductor memory devices are merely examples, and specific configuration and the like are appropriately adjustable.

For example, as described with reference to FIG. 1 and the like, the kerf region R_{KY} of the semiconductor memory devices according to the first embodiment and the second embodiment includes the stacked body regions R_{SS} and the non-stacked body region R_{SN}. Further, as described with reference to FIG. 3, the stacked body region R_{SS} includes a part of the stacked body SS_{KL} disposed in the memory cell layer L_{MCL} and a part of the stacked body SS_{KU} disposed in the memory cell layer L_{MCU}. Moreover, as described with reference to FIG. 4, the non-stacked body region R_{SN} does not include the stacked bodies SS_{KL}, SS_{KU}.

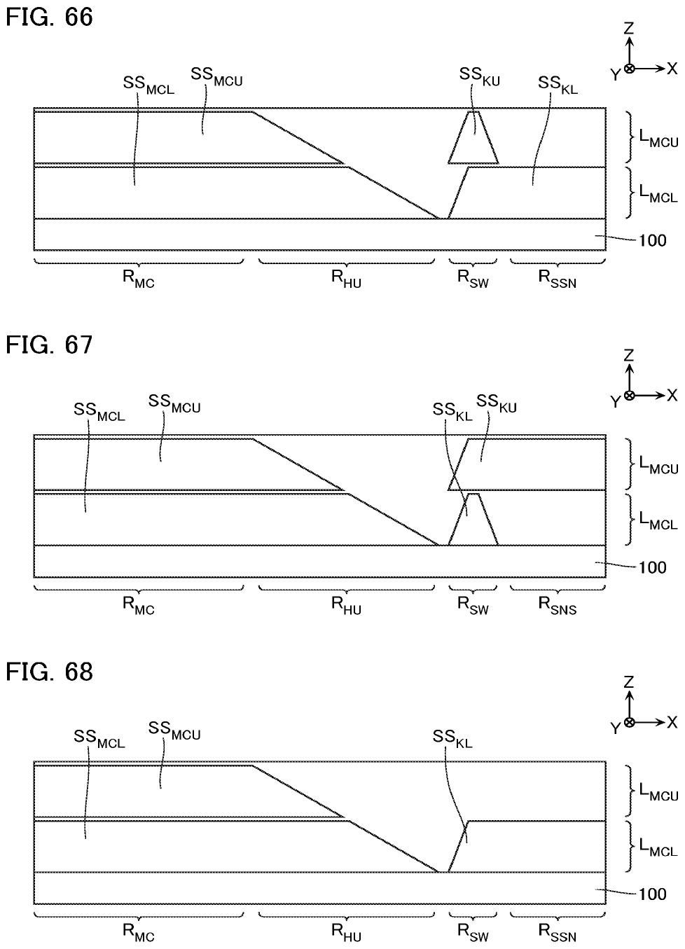

However, the kerf region R_{KY} may include a semi-stacked body region R_{SSN} as illustrated in FIG. 66 or a semi-stacked body region R_{SNS} as illustrated in FIG. 67. FIG. 66 and FIG. 67 are schematic cross-sectional views illustrating configurations of parts of semiconductor memory devices according to other embodiments. As illustrated in FIG. 66, the semi-stacked body region R_{SSN} includes a part of the stacked body SS_{KL} and does not include the stacked body SS_{KU}. As illustrated in FIG. 67, the semi-stacked body region R_{SNS} does not include the stacked body SS_{KL} and includes a part of the stacked body SS_{KU}. Note that, for example, in the kerf region R_{KY} exemplified in FIG. 1 and the like, the semi-stacked body regions R_{SSN}, R_{SNS} may be replaced with a part of the stacked body region R_{SS} or the non-stacked body region R_{SN}.

FIG. 68 to FIG. 70 are schematic cross-sectional views illustrating configurations of parts of semiconductor memory devices according to other embodiments.

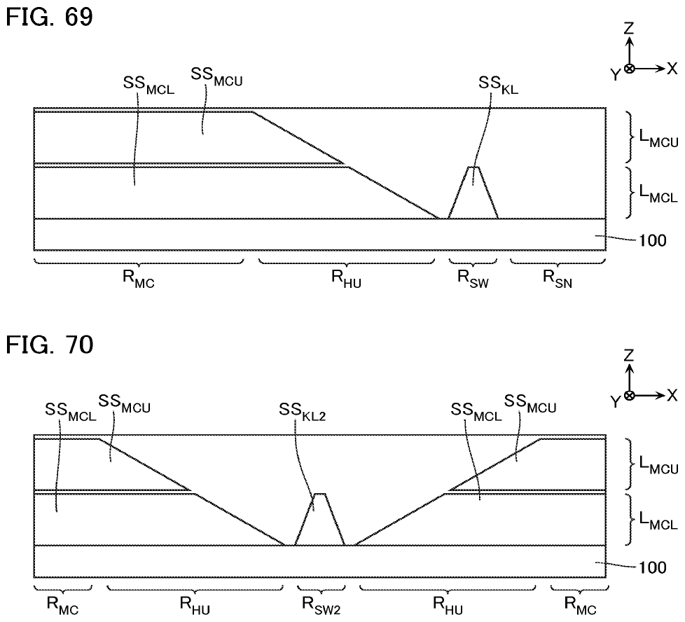

As described with reference to FIG. 56 and FIG. 36, in the comparative example, a variation in the film thickness T₁₆₄ in the Z-direction of the resist 164 formed between the inter-memory region R_{IM}′ (FIG. 55) and the hook-up region R_{HU} occurs between at the proximity of the non-stacked body region R_{SN} and at the proximity of the stacked body region R_{SS}. Here, in forming the memory cell layer L_{MCU}, since distances between the formed terrace portions TA and the kerf region R_{KY} are relatively large, such a variation in the film thickness T₁₆₄ in the Z-direction of the resist 164 is relatively small. Therefore, in the first embodiment and the second embodiment, as illustrated in FIG. 68 and FIG. 69, for example, in the memory cell layer L_{MCU}, the stacked body SS_{KU} in the stacked body region R_{SW} can be omitted. Further, in the second embodiment, as illustrated in FIG. 70, for example, in the memory cell layer L_{MCU}, the stacked body SS_{KU2} in the stacked body region R_{SW2} can be omitted.

[Others]

While certain embodiments have been described, these embodiments have been presented by way of example only, and are not intended to limit the scope of the inventions. Indeed, the novel devices and methods described herein may be embodied in a variety of other forms: furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a first memory plane region including a plurality of memory finger structures extending in a first direction and arranged in a second direction intersecting with the first direction; and
a kerf region arranged in the first direction with the first memory plane region and extending in the second direction, wherein
the plurality of memory finger structures include:
a first stacked body including a plurality of first conductive layers stacked in a stacking direction intersecting with the first direction and the second direction;
a plurality of semiconductor columns extending in the stacking direction and opposed to the plurality of first conductive layers;
a plurality of electric charge accumulating films disposed between the plurality of first conductive layers and the plurality of semiconductor columns; and
a plurality of first terrace portions disposed at end portions on a kerf region side in the first direction of the plurality of first conductive layers,
the kerf region includes a second stacked body including a plurality of first layers stacked in the stacking direction corresponding to at least a part of the plurality of first conductive layers, the second stacked body being spaced in the first direction from the first stacked body,
a first region in the kerf region is arranged in the first direction with a part of the plurality of memory finger structures and includes a part of the second stacked body,
a second region in the kerf region is arranged in the first direction with another part of the plurality of memory finger structures, is arranged in the second direction with the first region in the kerf region, and does not include the second stacked body, and
a third region in the kerf region extends in the second direction along an end portion on a first memory plane region side in the first direction of the kerf region, is arranged in the first direction with the first region and the second region, and includes another part of the second stacked body.

2. The semiconductor memory device according to claim 1, wherein
the third region extends in the second direction along from one end to the other end in the second direction of the plurality of memory finger structures arranged in the second direction.

3. The semiconductor memory device according to claim 2, wherein
a distance in the first direction between the first stacked body included in the plurality of memory finger structures and the another part of the second stacked body included in the third region in the kerf region is approximately constant from the one end to the other end in the second direction of the plurality of memory finger structures.

4. The semiconductor memory device according to claim 1, wherein
each of the plurality of first layers includes one or both of an insulating layer and a conductive layer.

5. The semiconductor memory device according to claim 1, further comprising
a second conductive layer arranged in the stacking direction with the first stacked body and connected to the plurality of semiconductor columns, wherein
the plurality of memory finger structures further include a third stacked body disposed on a side opposite to the second conductive layer in the stacking direction with respect to the first stacked body and including a plurality of third conductive layers stacked in the stacking direction, and
the plurality of semiconductor columns are further opposed to the plurality of third conductive layers.

6. The semiconductor memory device according to claim 5, wherein
the kerf region further includes a fourth stacked body including a plurality of second layers stacked in the stacking direction corresponding to at least a part of the plurality of third conductive layers, the fourth stacked body being spaced in the first direction from the third stacked body,
the first region includes a part of the fourth stacked body,
the second region does not include the fourth stacked body, and
the third region includes another part of the fourth stacked body.

7. The semiconductor memory device according to claim 6, wherein
the third region extends in the second direction along from one end to the other end in the second direction of the plurality of memory finger structures arranged in the second direction, and
a distance in the first direction between the third stacked body included in the plurality of memory finger structures and the another part of the fourth stacked body included in the third region is approximately constant from the one end to the other end in the second direction of the plurality of memory finger structures.

8. The semiconductor memory device according to claim 6, wherein
each of the plurality of second layers includes one or both of an insulating layer or a conductive layer.

9. The semiconductor memory device according to claim 1, further comprising:
a second memory plane region disposed on a side opposite to the kerf region in the first direction with respect to the first memory plane region, the second memory plane region being adjacent to the first memory plane region in the first direction; and
a fifth stacked body disposed between the first memory plane region and the second memory plane region and including a plurality of third layers stacked in the stacking direction corresponding to at least a part of the plurality of first conductive layers, wherein
the plurality of memory finger structures included in the first memory plane region further include a plurality of second terrace portions disposed at end portions on a fifth stacked body side in the first direction of the plurality of first conductive layers, and
a length in the first direction of the fifth stacked body is smaller than a length in the first direction of the first stacked body.

10. The semiconductor memory device according to claim 9, wherein
the fifth stacked body extends in the second direction along from one end to the other end in the second direction of the plurality of memory finger structures arranged in the second direction.

11. The semiconductor memory device according to claim 10, wherein
a distance in the first direction between the first stacked body included in the plurality of memory finger structures and the fifth stacked body is approximately constant from the one end to the other end in the second direction of the plurality of memory finger structures.

12. The semiconductor memory device according to claim 9, wherein
a distance in the first direction between the first stacked body included in the plurality of memory finger structures and the another part of the second stacked body included in the third region in the kerf region approximately matches a distance in the first direction between the first stacked body included in the plurality of memory finger structures and the fifth stacked body.

13. The semiconductor memory device according to claim 9, further comprising
a second conductive layer arranged in the stacking direction with the first stacked body and connected to the plurality of semiconductor columns, wherein
the plurality of memory finger structures further include a third stacked body disposed on a side opposite to the second conductive layer in the stacking direction with respect to the first stacked body and including a plurality of third conductive layers stacked in the stacking direction,
the plurality of semiconductor columns are further opposed to the plurality of third conductive layers,
the device further includes a sixth stacked body arranged in the stacking direction with the fifth stacked body and including a plurality of fourth layers stacked in the stacking direction corresponding to at least a part of the plurality of third conductive layers, and
a length in the first direction of the sixth stacked body is smaller than a length in the first direction of the third stacked body.

14. The semiconductor memory device according to claim 13, wherein
the sixth stacked body extends in the second direction along from one end to the other end in the second direction of the plurality of memory finger structures arranged in the second direction, and
a distance in the first direction between the third stacked body included in the plurality of memory finger structures and the sixth stacked body is approximately constant from the one end to the other end in the second direction of the plurality of memory finger structures.

15. The semiconductor memory device according to claim 13, wherein
each of the plurality of fourth layers includes one or both of an insulating layer or a conductive layer.

16. A semiconductor memory device comprising:
two memory plane regions adjacent in a first direction; and
a stacked body disposed between the two memory plane regions, wherein
the two memory plane regions include a plurality of memory finger structures extending in the first direction and arranged in a second direction intersecting with the first direction,
the plurality of memory finger structures include:
a plurality of first conductive layers stacked in a stacking direction intersecting with the first direction and the second direction;
a plurality of semiconductor columns extending in the stacking direction and opposed to the plurality of first conductive layers;
a plurality of electric charge accumulating films disposed between the plurality of first conductive layers and the plurality of semiconductor columns; and
a plurality of terrace portions disposed at end portions on a stacked body side in the first direction of the plurality of first conductive layers,
the stacked body includes a plurality of layers stacked in the stacking direction corresponding to at least a part of the plurality of first conductive layers,
a length in the first direction of the stacked body is smaller than lengths in the first direction of the plurality of memory finger structures in each of the two memory plane regions, and
the stacked body extends in the second direction along from one end to the other end in the second direction of the plurality of memory finger structures arranged in the second direction.

17. The semiconductor memory device according to claim 16, wherein
a distance in the first direction between the plurality of memory finger structures and the stacked body is approximately constant from the one end to the other end in the second direction of the plurality of memory finger structures.

18. The semiconductor memory device according to claim 16, further comprising
a second conductive layer arranged in the stacking direction with the plurality of first conductive layers and connected to the plurality of semiconductor columns, wherein
the plurality of memory finger structures further include a plurality of third conductive layers disposed on a side opposite to the second conductive layer in the stacking direction with respect to the plurality of first conductive layers and stacked in the stacking direction, and
the plurality of semiconductor columns are further opposed to the plurality of third conductive layers.

19. The semiconductor memory device according to claim 18, further comprising
another stacked body arranged in the stacking direction with the stacked body and including a plurality of other layers stacked in the stacking direction corresponding to at least a part of the plurality of third conductive layers, wherein
a length in the first direction of the another stacked body is smaller than the lengths in the first direction of the plurality of memory finger structures in each of the two memory plane regions.

20. The semiconductor memory device according to claim 19, wherein
the another stacked body extends in the second direction along from the one end to the other end in the second direction of the plurality of memory finger structures, and
a distance in the first direction between the plurality of memory finger structures and the another stacked body is approximately constant from the one end to the other end in the second direction of the plurality of memory finger structures.
